(19) United States
(12) Patent Application Publication
(10) Pub. No.: US 2024/0363745 A1
(43) Pub. Date: Oct. 31, 2024

(54) HIGH-FREQUENCY GROUP III-NITRIDE-BASED HIGH ELECTRON MOBILITY TRANSISTORS WITH HIGH-ALUMINUM CONCENTRATION BARRIERS AND RECESSED GATES

(71) Applicant: Wisconsin Alumni Research Foundation, Madison, WI (US)

(72) Inventors: Chirag Gupta, Middleton, WI (US); Swarnav Mukhopadhyay, Madison, WI (US); Shubhra Shweta Pasayat, Middleton, WI (US); Jiahao Chen, Madison, WI (US)

(21) Appl. No.: 18/308,386

(22) Filed: Apr. 27, 2023

(51) Int. Cl. H01L 29/778; H01L 29/06; H01L 29/20

(52) U.S. Cl. CPC H01L 29/7786; H01L 29/0607; H01L 29/2003

(57) ABSTRACT

Group III-nitride based high electron mobility transistors (HEMTs) are provided. The HEMTs combine a high-aluminum-content barrier layer with a recessed gate that provides the HEMTs with a very low channel sheet resistance and enables high-power, high-frequency operation. A thick barrier layer increases the distance between the two-dimensional electron gas (2DEG) channel and traps at the exposed surface of the group III-nitride barrier layer, thereby reducing or eliminating current collapse. The recessed gate provides a reduced barrier layer thickness below the gate, reducing the distance between the gate and allowing for good modulation of the 2DEG by the gate.

### REFERENCE TO GOVERNMENT RIGHTS

This invention was made with government support under N00014-22-1-2267 awarded by the Office of Naval Research/DOD. The government has certain rights in the invention.

### BACKGROUND

The growth of III-Nitride materials has matured in the past two decades. Extensive research on III-Nitride materials has expedited the production of the high electron mobility transistors (HEMTs) which are revolutionizing the radiofrequency (RF) communication field. Specifically, AlGaN/GaN HEMTs are rapidly taking over the market in the high-speed communication domain and the power electronics industry owing to their high power and high-frequency operation capability. The exponentially growing interest in the industry requires continuous development of the AlGaN/GaN HEMTs to enhance their performance beyond the state-of-the-art. One of the most challenging aspects of advancing the AlGaN/GaN HEMT technology is the growth of crack-free, thick AlGaN layers with a high Al concentration. This combination is needed to reduce gate leakage and to enable an increased breakdown voltage while maintaining a low sheet resistance. This is especially significant for scaled RF devices where the high electric field at the drain side gate edge often leads to an excessive gate leakage causing soft breakdown. Apart from the gate leakage, the high breakdown field of the high-composition AlGaN barrier layer will help to increase the breakdown voltage of the HEMT.

The limitation of growing thick AlGaN barrier layers having a high Al concentration arises from the critical layer thickness of the AlGaN barrier layer grown on a thick GaN buffer layer due to a 3.5% lattice mismatch between AlN and GaN. If the barrier layer thickness exceeds the critical layer thickness, then the AlGaN layer will crack due to the high tensile strain in this film. However, a higher AlGaN barrier layer thickness is desirable because it results in higher polarization-induced charges in the channel, which is required to obtain low sheet resistance.

Another crucial challenge is that a higher Al concentration in the AlGaN barrier layer shifts the two-dimensional electron gas (2DEG) wavefunction towards the interface, causing increased alloy scattering and reduced electron mobility. Moreover, with increased 2DEG charge density, carrier-carrier scattering increases significantly in the channel, limiting electron mobility. Therefore, it is difficult to grow a sufficiently thick high-Al concentration AlGaN barrier layer for a HEMT structure with high 2DEG carrier density and simultaneously achieve a high mobility that is necessary for both power electronics and RF devices.

Additionally, most of the high-performance AlGaN/GaN HEMTs with room temperature sheet resistivity near 250 Ω/□ have been demonstrated with SiC substrates, which are cost-limiting. There have been very few reports of AlGaN/GaN HEMTs with sheet resistivity of near or less than 250 Ω/□, with most of them on SiC substrates. (Yamada, Atsushi et al. Journal of Crystal Growth 560-561 (Apr. 15, 2021): 126046; Wang, Xiaoliang et al. Journal of Crystal Growth, Thirteenth International Conference on Metal Organic Vapor Phase Epitaxy (ICMOVPE XIII), 298 (Jan. 1, 2007): 835-39; Gaska, R. et al. Applied Physics Letters 72, no. 6 (Feb. 9, 1998): 707-9.) It is challenging to achieve low sheet resistivity in AlGaN/GaN HEMT structures grown on sapphire substrates due to the high density of defects and dislocations generated due to the lattice mismatch (16%) between GaN and sapphire. Also, due to the high optical phonon scattering and scattering due to polarization-induced charges at the interface, it is very difficult to achieve sheet resistivity below 250 Ω/□. (Cao, Yu et al. Applied Physics Letters 92, no. 15 (Apr. 14, 2008): 152112.) The lowest recorded sheet resistivity in AlGaN/GaN HEMT on SiC so far is 211 Ω/□ by Yamada et al. using a high-Al concentration Al_{0.68}Ga_{0.32}N (layer thickness 6 nm) barrier layer. (Yamada et al., 2021.)

Moreover, maintaining a sharp and smooth interface is crucial for obtaining high electron mobility, which is difficult for a high-Al concentration AlGaN barrier layer. The interface quality will degrade as the thickness of the high-composition AlGaN barrier layer is increased due to strain. (Yamada et al., 2021.)

Another concern is the presence of high carbon concentration in the metal-organic chemical vapor deposition (MOCVD) grown GaN channel layer also increases the channel resistance. So, the reduction of carbon in the GaN channel layer is one of the important requirements for improving sheet resistance. Solving these issues would have great implications in terms of improving the performance of high-power and high-frequency HEMT devices.

### SUMMARY

Group III-nitride based HEMTs that combine a high-aluminum-content group III-nitride barrier layer with a recessed gate are provided. Examples of some embodiments of the HEMTs are listed below.

Embodiment 1 of a high electron mobility transistor includes: a channel layer comprising Ga-polar unintentionally-doped GaN; a barrier layer having a thickness, t₂, of at least 30 nm and comprising AlₓGa₁₋ₓN where 0.3≤x, InₓAl₁₋ₓN, where x<0.25, or InₓGa_{y}Al_{1-(x+y)}N, where (x+y)<0.8; an AlN interlayer disposed between the channel layer and the barrier layer; a two-dimensional electron gas confined in the channel layer; a source in electrical communication with the two-dimensional electron gas; a drain in electrical communication with the two-dimensional electron gas; and a gate between the source and the drain, wherein a portion of the gate is recessed into the AlₓGa₁₋ₓN, InₓAl₁₋ₓN, or InₓGa_{y}Al_{1-(x+y)}N.

Embodiment 2 of a high electron mobility transistor includes Embodiment 1, wherein the barrier layer comprises the AlₓGa₁₋ₓN.

Embodiment 3 of a high electron mobility transistor includes Embodiment 1 or Embodiment 2, wherein the two-dimensional electron gas has a room temperature sheet resistance of 325 Ω/□ or less.

Embodiment 4 of a high electron mobility transistor includes Embodiment 2 or Embodiment 3, wherein 0.3≤x≤0.4.

Embodiment 5 of a high electron mobility transistor includes any of Embodiments 2-4, wherein the layer of the AlₓGa₁₋ₓN has a thickness in the range from 30 nm to 50 nm.

Embodiment 6 of a high electron mobility transistor includes Embodiment 2, wherein the two-dimensional electron gas has a room temperature sheet resistance in the range from 200 Ω/□ to 325Ω/□, 0.3≤x≤0.4, and the layer of the AlₓGa₁₋ₓN has a thickness in the range from 30 nm to 50 nm.

Embodiment 7 of a high electron mobility transistor includes any of Embodiments 1-6, wherein the gate has a gate length of less than 150 nm.

Embodiment 8 of a high electron mobility transistor includes any of Embodiments 1-7, wherein the high electron mobility transistor is a depletion mode high electron mobility transistor.

Embodiment 9 of a high electron mobility transistor includes any of Embodiments 1-8, wherein t₁<t₂<20×t₁, where t₁ is a local thickness of the barrier layer between the recessed portion of the gate and the AlN layer, and further wherein the gate is a T-shaped gate and a cap of the T-shaped gate is spaced apart from the barrier layer by a distance, t_{space}.

Embodiment 10 of a high electron mobility transistor includes any of Embodiments 1-9, wherein the two-dimensional electron gas has an electron density beneath the portion of the gate that is recessed of at least 5×10¹² cm⁻² and an electron density of at least 8×10¹² cm⁻² elsewhere.

Embodiment 11 of a high electron mobility transistor includes any of Embodiments 1-10, wherein the AlₓGa₁₋ₓN, InₓAl₁₋ₓN, or InₓGa_{y}Al_{1-(x+y)}N of the barrier layer has a graded composition.

Embodiment 12 of a high electron mobility transistor includes any of Embodiments 1-10, wherein the AlₓGa₁₋ₓN, InₓAl₁₋ₓN, or InₓGa_{y}Al_{1-(x+y)}N of the barrier layer has a superlattice structure.

Embodiment 13 of a high electron mobility transistor includes any of Embodiments 1-12, further comprising a buffer layer comprising graded AlₓGa₁₋ₓN, where x ranges from 0 to 0.1 disposed between the AlN interlayer and the channel layer.

Embodiment 14 of a high electron mobility transistor includes: a channel layer comprising Ga-polar unintentionally-doped GaN; a barrier layer comprising AlₓGa₁₋ₓN where 0.3≤x, InₓAl₁₋ₓN, where x<0.25, or InₓGa_{y}Al_{1-(x+y)}N, where (x+y)<0.8; an AlN intervening layer disposed between the channel layer and the barrier layer; a two-dimensional electron gas confined in the channel layer; an etch stop layer on the barrier layer, the etch stop layer comprising an AlGaN alloy having an aluminum content at least 15 mol. % greater than the aluminum content of the barrier layer; a trench layer on the etch stop layer, the trench layer comprising an (Al,Ga)N alloy having an aluminum content at least 15 mol. % lower than the aluminum content of the barrier layer; a source in electrical communication with the two-dimensional electron gas; a drain in electrical communication with the two-dimensional electron gas; and a gate between the source and the drain, wherein a portion of the gate is recessed through the trench layer down to the etch stop layer.

Embodiment 15 of a high electron mobility transistor includes Embodiment 14, wherein the barrier layer, etch stop layer, and trench layer have combined thickness of at least 10 nm.

Embodiment 16 of a high electron mobility transistor includes Embodiment 14 or Embodiment 15, where in the barrier layer comprises the AlₓGa₁₋ₓN, where 0.30≤x<0.5.

Embodiment 17 of a high electron mobility transistor includes any of Embodiments 14-16, wherein the aluminum content of the (Al,Ga)N alloy of the trench layer is graded through the thickness of the trench layer.

Embodiment 18 of a high electron mobility transistor includes any of Embodiments 14-16, wherein the (Al,Ga)N alloy of the trench layer has an AlN/GaN superlattice structure or an AlGaN/GaN superlattice structure.

Embodiment 19 of a high electron mobility transistor includes any of Embodiments 14-18, wherein the trench layer comprises a first sublayer comprising either GaN or an AlGaN alloy having an Al content of less than 10 mol. % on the etch stop layer and a second sublayer comprising the (Al,Ga)N alloy having an aluminum content at least 15 mol. % lower than the aluminum content of the barrier layer.

Embodiment 20 of a high electron mobility transistor includes any of Embodiments 14-19, wherein the AlₓGa₁₋ₓN, InₓAl₁₋ₓN, or InₓGa_{y}Al_{1-(x+y)}N of the barrier layer has a graded composition.

Embodiment 21 of a high electron mobility transistor includes any of Embodiments 14-19, wherein the AlₓGa₁₋ₓN, InₓAl₁₋ₓN, or InₓGa_{y}Al_{1-(x+y)}N of the barrier layer has a superlattice structure.

Embodiment 22 of a high electron mobility transistor includes any of Embodiments 14-21, further comprising a buffer layer comprising graded AlₓGa₁₋ₓN, where x ranges from 0 to 0.1 disposed between the AlN interlayer and the channel layer.

Embodiment 23 of a high electron mobility transistor includes: a channel layer comprising Ga-polar unintentionally-doped GaN; a barrier layer comprising AlₓGa₁₋ₓN where 0.3≤x, InₓAl₁₋ₓN, where x<0.25, or InₓGa_{y}Al_{1-(x+y)}N, where (x+y)<0.8; an AlN intervening layer disposed between the channel layer and the barrier layer; a two-dimensional electron gas confined in the channel layer; a trench layer on the barrier layer, the trench layer comprising an (Al,Ga)N alloy having an aluminum content at least 15 mol. % lower than the aluminum content of the AlₓGa₁₋ₓN, InₓAl₁₋ₓN, or InₓGa_{y}Al_{1-(x+y)}N in the barrier layer; a source in electrical communication with the two-dimensional electron gas; a drain in electrical communication with the two-dimensional electron gas; and a gate between the source and the drain, wherein a portion of the gate is recessed through the trench layer down to the barrier layer.

Embodiment 24 of a high electron mobility transistor includes Embodiment 23, wherein the barrier layer and trench layer have combined thickness of at least 10 nm.

Embodiment 25 of a high electron mobility transistor includes Embodiment 23 or Embodiment 24, where in the barrier layer comprises the AlₓGa₁₋ₓN, where 0.30≤x<0.5.

Embodiment 26 of a high electron mobility transistor includes any of Embodiments 23-25, wherein the aluminum content of the (Al,Ga)N alloy of the trench layer is graded through the thickness of the trench layer.

Embodiment 27 of a high electron mobility transistor includes any of Embodiments 23-25, wherein the (Al,Ga)N alloy of the trench layer has an AlN/GaN superlattice structure.

Embodiment 28 of a high electron mobility transistor includes any of Embodiments 23-27, wherein the trench layer comprises a first sublayer either GaN or an AlGaN alloy having an Al content of less than 10 mol. % on the barrier layer and a second sublayer comprising the (Al,Ga)N alloy having an aluminum content at least 15 mol. % lower than the aluminum content of the barrier layer.

Embodiment 29 of a high electron mobility transistor includes any of Embodiments 23-28, wherein the AlₓGa₁₋ₓN, InₓAl₁₋ₓN, or InₓGa_{y}Al_{1-(x+y)}N of the barrier layer has a graded composition.

Embodiment 30 of a high electron mobility transistor includes any of Embodiments 23-28, wherein the AlₓGa₁₋ₓN, InₓAl₁₋ₓN, or InₓGa_{y}Al_{1-(x+y)}N of the barrier layer has a superlattice structure.

Embodiment 31 of a high electron mobility transistor includes any of Embodiments 23-30, further comprising a buffer layer comprising graded AlₓGa₁₋ₓN, where x ranges from 0 to 0.1 disposed between the AlN interlayer and the channel layer.

Embodiment 32 of a high electron mobility transistor includes: an AlGaN channel layer; an AlN barrier layer having a thickness, t₂, of at least 30 nm; a two-dimensional electron gas confined in the AlGaN channel layer; a source in electrical communication with the two-dimensional electron gas; a drain in electrical communication with the two-dimensional electron gas; and a gate between the source and the drain, wherein a portion of the gate is recessed into the AlN barrier layer.

Embodiment 33 of a high electron mobility transistor includes Embodiment 32, wherein the AlN barrier layer has a thickness in the range from 40 nm to 100 nm.

Embodiment 34 of a high electron mobility transistor includes Embodiment 32 or Embodiment 34, wherein the high electron mobility transistor is a depletion mode high electron mobility transistor.

Embodiment 35 of a high electron mobility transistor includes any of Embodiments 32-34, wherein t₁<t₂<20×t₁, where t₁ is a local thickness of the AlN barrier layer between the recessed portion of the gate and the AlGaN channel layer, and further wherein the gate is a T-shaped gate and a cap of the T-shaped gate is spaced apart from the AlN barrier layer by a distance, t_{space}.

Embodiment 36 of a high electron mobility transistor includes: a channel layer comprising Ga-polar unintentionally-doped GaN; a bilayered barrier layer comprising a layer of InₓAl₁₋ₓN, where x<0.25, and a layer of AlₓGa₁₋ₓN, where 0.3≤x, on the layer of InₓAl₁₋ₓN; an AlN layer disposed between the channel layer and the layer of InₓAl₁₋ₓN; a two-dimensional electron gas confined in the channel layer; a source in electrical communication with the two-dimensional electron gas; a drain in electrical communication with the two-dimensional electron gas; and a gate between the source and the drain, wherein a portion of the gate is recessed into the layer of AlₓGa₁₋ₓN.

Embodiment 37 of a high electron mobility transistor includes Embodiment 36, further comprising an etch stop layer between the layer of AlₓGa₁₋ₓN and the layer of InₓAl₁₋ₓN.

Other principal features and advantages of the invention will become apparent to those skilled in the art upon review of the following drawings, the detailed description, and the appended claims.

### BRIEF DESCRIPTION OF THE DRAWINGS

Illustrative embodiments of the invention will hereafter be described with reference to the accompanying drawings, wherein like numerals denote like elements.

FIG. 1 shows a schematic diagram of a HEMT with a thick, high-Al content AlGaN, InAlN, or InGaAlN barrier and a recessed gate.

FIG. 2 shows a schematic diagram of a HEMT with a thick, high-Al content AlGaN, InAlN, or InGaAlN barrier, a recessed gate, and annealed source and drain.

FIG. 3 shows a schematic diagram of an AlGaN/AlN/GaN HEMT with a thick, high-Al content AlGaN barrier and a recessed gate, and including a growth substrate, buffer layer, capping layer, and passivation layer.

FIG. 4 shows a schematic diagram of an AlGaN/AlN/GaN HEMT with a thick, high-Al content AlGaN barrier, a recessed gate, and an etch stop layer.

FIGS. 5A-5F show HEMTs that include an etch stop layer over a barrier layer and a gate trench layer over the etch stop layer.

FIGS. 6A-6R show HEMTs that include an etch stop layer over a barrier layer and a trench layer over the etch stop layer with representative material compositions and layer thicknesses.

FIGS. 7A-7F show HEMTs in which the barrier layer is used as an etch stop layer for an overlying gate trench layer over the etch stop layer.

FIGS. 8A-8R show HEMTs in which the barrier layer is used as an etch stop layer for an overlying gate trench layer over the etch stop layer with representative material compositions and layer thicknesses.

FIGS. 9A and 9B show AlGaN/GaN HEMTs in which the AlN layer is grown on a graded AlₓGa₁₋ₓN buffer layer. This HEMT design can be implemented without an etch stop layer (FIG. 9A) or with an etch stop layer 420 (FIG. 9B).

FIGS. 10A and 10B show AlGaN/GaN HEMTs that include an etch stop in which the barrier material above the etch stop is graded. This HEMT design can be implemented without a graded AlGaN buffer layer (FIG. 10A) or with a graded AlGaN buffer layer (FIG. 10B).

FIGS. 11A-11H show additional embodiments of high-frequency AlGaN/GaN HEMTs that include an etch stop layer and a barrier comprising or consisting of a superlattice. The barrier may consist of a superlattice (FIGS. 11A-11D). The barrier may include both an AlGaN barrier layer and an overlying superlattice (FIGS. 11E-11H). The superlattice barrier may be used in combination with a graded AlGaN buffer layer (FIGS. 11B, 11D, 11F, and 11H) and/or a graded upper barrier layer (FIGS. 11C, 11D, 11G, and 11H).

FIG. 12 shows a schematic diagram of a depletion mode AlN/AlGaN HEMT with a thick barrier layer and a recessed gate.

FIG. 13 shows the epitaxial layer structure of an AlGaN/AlN/GaN HEMT structure.

FIGS. 14A-14B show (FIG. 14A) 2DEG sheet charge and mobility and (FIG. 14B) sheet resistance of different samples.

FIG. 15 shows high-resolution X-ray diffraction (HR-XRD) omega rocking curve measurements of different samples.

FIGS. 16A-16B show atomic force microscopy (AFM) height sensor scans of (FIG. 16A) sample 5 and (FIG. 16B) sample 6; FIG. 16C shows a phase sensor scan of sample 6 showing a micro-crack.

FIGS. 17A-17B show sheet resistance variation with AlGaN layer thickness for (FIG. 17A) different Al compositions and (FIG. 17B) different substrates.

FIG. 18A shows a schematic diagram of an AlGaN—InAlN/AlN/GaN HEMT.

FIG. 18B shows a schematic diagram of an AlGaN—InAlN/AlN/GaN HEMT with an etch stop layer.

### DETAILED DESCRIPTION

Group III-nitride based HEMTs are provided. The HEMTs combine a high-aluminum-content group III-nitride barrier layer with a recessed gate that provides the HEMTs with a very low channel sheet resistance and enables high-power, high-frequency operation.

In some embodiments of the HEMTs, the thick barrier layer is thick in order to increase the distance between the 2DEG channel and traps at the exposed surface of the group III-nitride barrier layer, thereby reducing or eliminating current collapse that is caused by the depletion of the 2DEG due to the capture of electrons in the surface traps under the influence of a gate-drain bias. The recessed gate provides a reduced barrier layer thickness below the gate, reducing the distance between the gate and allowing for good modulation of the 2DEG by the gate. This combination of features produces group III-nitride HEMTs that operate at high frequencies, including frequencies of 94 GHz or higher, and high power with low gate leakage, high breakdown voltages, and high cut-off frequencies. The group III-nitride HEMTs include those based on an AlGaN/GaN active region design, as well those based on an AlN/AlGaN active region design.

High-Frequency HEMTs with AlGaN, InAlN, or InGaAlN Barrier Layers.

One aspect of the invention provides HEMTs with a barrier/AlN/GaN structure, wherein the barrier is a thick layer of a high Al-content group III-nitride selected from AlGaN, InAlN, and InGaAlN and the gate is recessed. These HEMTs are characterized by 2DEG channels having high room temperature (“RT”; 23° C.) electron densities and mobilities and ultra-low RT sheet resistance. For example, HEMTs having RT electron densities greater than 5×10¹² cm⁻³, RT electron mobilities of at least 1700 cm²/V·s, and RT sheet resistance of less than 400 Ω/□, as determined by Hall measurement using the Van-Der-Pauw method, are provided. This includes HEMTs having RT electron densities greater than 1×10¹³ cm⁻², and/or RT electron mobilities of at least 1700 cm²/V·s, and/or RT sheet resistance of less than 325 250 Ω/□, including less than 250 Ω/□. By way of further illustration, some embodiments of the HEMTs have RT electron densities in the range from 7×10¹² cm⁻² to 2×10¹³ cm⁻², and/or RT electron mobilities in the range from 1600 cm²/V·s to 2200 cm²/V·s, and/or RT sheet resistance in the range from 200 Ω/□ to 250 Ω/□.

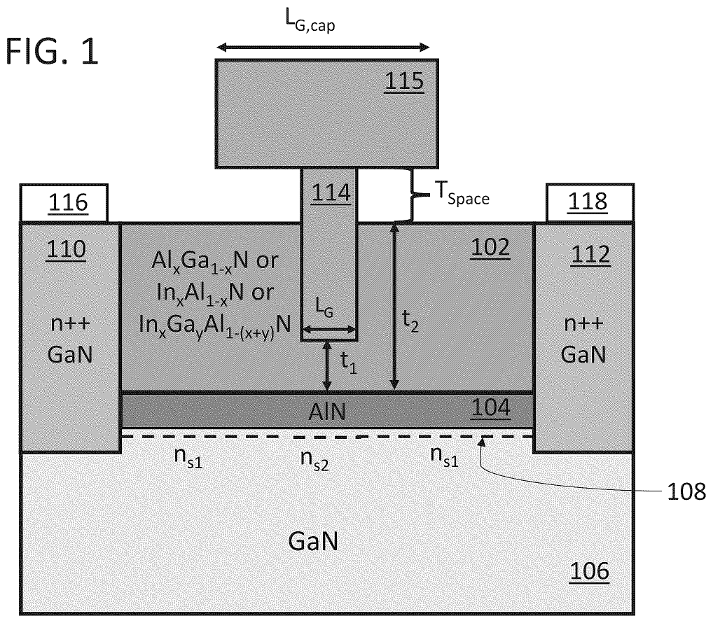

One illustrative embodiment of such a HEMT is shown in the schematic diagram of FIG. 1. The HEMT includes an AlₓGa₁₋ₓN barrier layer 102, where 0.3≤x, an InₓAl₁₋ₓN barrier layer 102, where x<0.25, or an InₓGa_{y}Al_{1-(x+y)}N barrier layer 102, where (x+y)<0.8. Some embodiments of the HEMTs use an AlₓGa₁₋ₓN barrier layer, where 0.3≤x<0.5. Some embodiments of the HEMTs use an InₓAl₁₋ₓN barrier layer, where 0.1<x<0.25. Some embodiments of the HEMTs use an InₓGa_{y}Al_{1-(x+y)}N barrier layer, where 0.04<x<0.15 and 0.15<y<0.76.

The HEMT further includes an unintentionally-doped, Ga-polar GaN channel layer 106 separated from the barrier layer by an AlN intervening layer 104. Because the AlGaN, InAlN, or InGaAlN has a wider bandgap than the GaN, the bandgap discontinuity results in charge transfer from the AlGaN, InAlN, or InGaAlN to the GaN and accumulation of charge at the interface, resulting in the formation of a 2DEG 108 (dashed line) just below the interface. 2DEG 108 has a high electron density and a high electron mobility and acts as a channel for electron current to flow from a source (S) 110 to a drain (D) 112. A voltage applied to a gate 114 that is positioned above the 2DEG channel between source 110 and contact 112 is used to modulate the flow of electrons in the 2DEG. As shown in FIG. 1, gate 114 may be a T-shaped gate having a recessed portion and a gate cap 115 to allow for a lower gate resistance. A source contact 116 is disposed on source 110 and a drain contact 118 is disposed on drain 112.

During operation, a positive bias potential is applied to drain 112, while source 110 is grounded. As a result, an electron current flows from source 110 to drain 112, and this electron current is controlled by a potential applied to gate 114.

Group III-nitrides, including AlGaN, InGaN, InGaAlN, and AlN, lack native surface oxides, which results in the presence of unpassivated surface states or “traps.” The surface states act as electron traps. Under the influence of high electric fields, which occur during the gate-drain biasing, electrons from the 2DEG channel can be captured in the surface traps. Because the trap states have a response time on the order of milliseconds, at high-frequency operation, the traps do not release the captured electrons. This results in a reduced current in the channel, which is referred to as current collapse. In the HEMTs described herein, a thick barrier layer is used to address the problem of current collapse.

In some embodiments, barrier layer 102 has a thickness (t₂) of at least 30 nm, which has the advantage of increasing the distance between the surface traps at the exposed barrier layer surface and the 2DEG in order to avoid current collapse during high-frequency operation. However, it is advantageous to have a thin barrier layer thickness between gate 114 and 2DEG 108 in order to improve the gate modulation and suppress short channel effects that can interfere with HEMT operation for high-frequency HEMTs, which have very small gate lengths. Thus, in the HEMTs described herein, the gate is recessed into the barrier layer in order to reduce the thickness of the barrier locally between the recessed end of the gate and the 2DEG. This is shown in FIG. 1, where t₁ represents the local thickness of the barrier layer beneath gate 114 and L_{G} is the gate length. Thickness t₁ is substantially lower than t₂, and t₂ is typically, but not necessarily, lower than 20t₁. The recessed-gate, high-frequency HEMTs may be designed for normally on (depletion mode) operation or, if the gate is recessed sufficiently deeply to reduce the distance between the gate and the channel, for normally off (enhancement mode) operation. However, the primary purpose of the recessed-gate design is to achieve good modulation of the 2DEG, while simultaneously avoiding current collapse, rather than to provide enhancement mode operation.

Gate lengths for the AlGaN/GaN, InAlN/GaN, and InGaAlN/GaN based HEMTs operating at frequencies of 30 GHz or higher are typically 250 nm or shorter, and may be 150 nm or shorter. For example, high-frequency AlGaN/GaN HEMTs that operate in the frequency range from about 30 GHz to 100 GHz may have gate lengths in the range from 40 nm to 250 nm. This includes high-frequency HEMTs that operate at frequencies of 80 GHz or higher, 90 GHz or higher, and greater than 94 GHz having gate lengths in the range from 40 nm to 100 nm. (It should be understood, however, that the HEMTs described herein are not limited to those having gate lengths in these ranges or operating at these frequencies.) To achieve good gate modulation and high-frequency performance with such small gate lengths, the HEMTs can be fabricated with a ratio of L_{G} to t₁ (L_{G}/t₁) of at least 3 and more desirably an L_{G}/t₁ of at least 10.

As a result of the reduced barrier thickness beneath the recessed gate, 2DEG 108 will have a lower electron density (nₛ₂) beneath gate 114, relative to the electron density (nₛ₁) beneath the thicker portions of barrier layer 102. Generally, it is desirable to have a minimum electron density of 5×10¹² cm⁻² in the channel. In order to offset the effect of a thin barrier on 2DEG carrier density beneath gate 114, an AlₓGa₁₋ₓN barrier layer 102, where 0.3≤x, an InₓAl₁₋ₓN barrier layer, where x<0.25, or an InₓGa_{y}Al_{1-(x+y)}N barrier layer, where (x+y)<0.8 is used to provide a high carrier density and, therefore, a lower sheet resistance, for high-frequency and high-power performance. This includes AlₓGa₁₋ₓN barrier layers, in which 0.31≤x, in which 0.31≤x, and in which 0.36≤x.

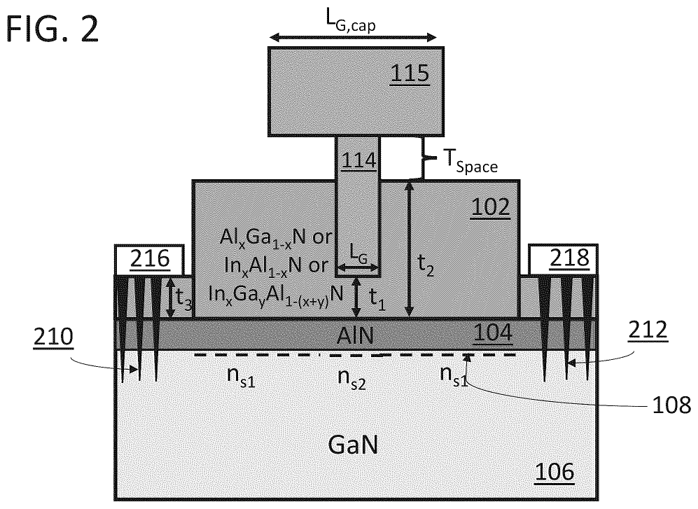

Source 110 and drain 112 may comprise regrown highly n-type (n⁺⁺) GaN. The highly n-type doped semiconductor material may have an n-type dopant concentration of, for example, at least 10²⁰/cm³. Alternatively, the source and drain may be annealed contacts, as shown in FIG. 2. Annealed contacts for the source 210 and drain 212 are fabricated by removing part of the AlGaN, InAlN, or InGaAlN, etching columns through the remaining AlGaN, InAlN, or InGaAlN material and AlN intervening layer 104 and into GaN channel layer 106. A metal is then deposited into the channels and annealed to form recessed, low resistance ohmic contacts. Another metal layer is then deposited on the recessed ohmic contacts to form the source 216 and drain 218 contacts.

Various metals and metal alloys can be used to form the source 116, 216 and drain 118, 218 contacts, recessed ohmic contacts 210, 212, and gate 114. By way of illustration only, the source, drain, and recessed ohmic contacts can be composed of titanium, aluminum, nickel, gold, or alloys thereof, and the gate may be composed of titanium, platinum, chromium, nickel, or alloys of titanium and tungsten. In one embodiment, the contacts comprise an alloy of nickel, silicon, and titanium that is formed by depositing respective layers of these materials, and then annealing them.

The HEMTs are grown epitaxially on a substrate (not shown in FIGS. 1 and 2) and may include buffer layers and/or nucleation layers to facilitate the growth of high-quality crystalline layers epitaxially on a lattice mismatched substrate. Suitable substrates include sapphire, SiC, and silicon. The composition, grading, and thickness of any intervening buffer layers will depend on the substrate upon which the active region of the HEMT is grown. By way of illustration, graded semi-insulating GaN can be used as a buffer layer for the growth of a GaN channel layer on a sapphire substrate, while an AlN nucleation layer with or without a semi-insulating GaN buffer layer can be used for the growth of a GaN channel layer on SiC. The semi-insulating GaN may be Fe- or C-doped GaN in order to trap background carriers in the GaN buffer layer.

In addition, capping layers for offsetting current leakage and/or passivation layers for burying trapping states at the barrier layer surface to reduce current collapse may be deposited over the exposed surface of the barrier layers. Examples of passivating materials include Si₃N₄, AlN, SiO₂, SiNO, Al₂O₃, and HfO₂. The capping layer is a thin layer, typically of GaN, on the barrier layer that reduces gate leakage. If a capping layer is used, a passivation layer may be disposed over the capping layer. In should be noted, however, that while capping and passivation layers can help to reduce current collapse at operating frequencies of ˜30 GHz or lower (e.g., 10 GHz), they are not effective at higher frequencies, such as frequencies of 90 GHz or higher.

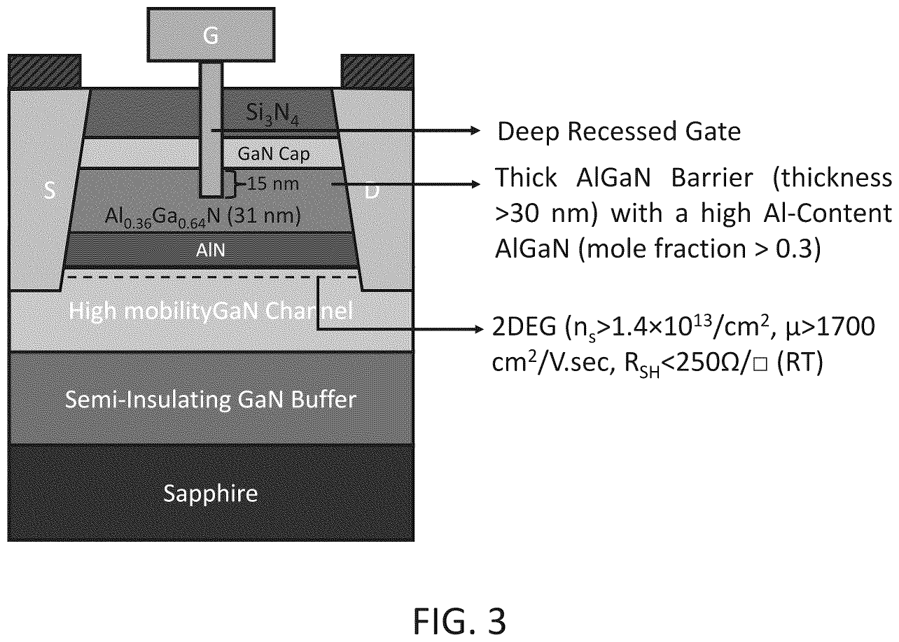

FIG. 3 is a schematic diagram of one illustrative embodiment of a high-frequency HEMT that is capable of operating at a frequency of at least 94 GHz with a room temperature (RT; 23° C.) sheet resistance of 250 Ω/□ or lower. The HEMT includes a c-plane sapphire substrate, a semi-insulating GaN buffer layer, a Ga-polar unintentionally-doped GaN channel layer, an AlN intervening layer, a thick, high-aluminum concentration AlGaN barrier layer, a GaN capping layer, a Si₃N₄ passivation layer, and a recessed gate.

The various Group III-nitride layers, such as buffer layers, nucleation layers, channel layers, intervening layers, barrier layers, and capping layers, of the high-frequency HEMTs can be grown using vapor deposition methods, such as metal-organic chemical vapor deposition (MOCVD), plasma chemical vapor deposition (CVD), or hot-filament CVD, or by molecular beam epitaxy (MBE). The metal contacts can be deposited by metal deposition techniques, such as atomic layer deposition (ALD), sputtering, or evaporation.

The growth of the barrier/AlN/GaN HEMT heterostructure takes place in a vacuum chamber in which the substrate typically is supported on a rotatable platform. A heat source (e.g., a resistive heater) in thermal communication with the growing heterostructure can be used to tailor the growth temperature for each of the various layers to provide high-quality crystal growth. Typical growth temperatures include temperatures in the range from about 400° C. to about 1500° C. and, more commonly, in the range from about 1000° C. to about 1300° C.; however, suitable growth temperatures will depend on the particular material being grown.

Epitaxial growth using vapor deposition is carried out by exposing the substrate or the growing heterostructure to metal-containing and nitrogen-containing precursor molecules that decompose and react to form the various layers of the HEMT. These precursors may be introduced into the vacuum chamber with a carrier gas, such as hydrogen or nitrogen. For MOCVD growth, the precursors are metal organic compounds, such as trimethyl gallium (TMGa), triethyl gallium (TEGa), trimethyl aluminum (TMAl), triethyl aluminum (TEAl), trimethyl indium (TMI), and triethethyl indium (TEI). Ammonia (NH₃) is typically used as a nitrogen precursor molecule. For the growth of doped semiconductors, a dopant-containing precursor (e.g., silane for Si doping) is also introduced into the chamber.

The thickness of the Ga-polar GaN channel is typically in the range from about 50 nm to 2000 nm, including in the range from 1000 nm to 2000 nm. Thicknesses outside of this range can be used. However, a thicker channel layer has the advantage of increasing the distance between the 2DEG and carrier trapping states present at the interface between the GaN channel layer and the buffer layer on which the channel layer is grown. Like the trapping states at the surface of the barrier layer, these interface trapping states can contribute to current collapse.

In order to grow a high-quality (low-defect) AlGaN, InAlN or InGaAlN barrier layer, the processing conditions for said layer must be carefully tailored because, as the Al composition in the barrier increases, the crystal lattice mismatch between AlGaN, InAlN, or InGaAlN and GaN increases, which tends to deteriorate the crystal quality by creating cracks and surface traps. Moreover, as the Al content of the barrier layer increases, the critical thickness of the AlGaN, InAlN, or InGaAlN is reduced and, as a result, the crystal quality tends to decrease as the thickness of the layer increases. For these reasons, the growth rate of the high-aluminum content barrier layer should be slow—no greater than 7 nm/min—in order to reduce the strain in the layer during growth and provide a higher critical layer thickness. Without intending to be bound to any particular theory behind the improved growth mechanism, it is proposed that the lower growth rate allows atoms within the AlGaN, InAlN, or InGaAlN epitaxial layer to relax and reorder during layer growth to form a more ordered crystal. For extremely slow growth, TEGa is a preferred gallium precursor for AlGaN and InGaAlN.

The quality of the barrier layer is also improved by including an intervening AlN layer between the GaN channel layer and the barrier layer. This is advantageous because the lattice constant mismatch between AlN and AlGaN, InAlN, or InGaAlN is lower than that between GaN and AlGaN, InAlN, or InGaAlN. The intervening AlN layer can be very thin, having, for example, a thickness of less than 5 nm or even less than 2 nm. By way of illustration only, AlN layers having thicknesses in the range from 0.5 to 2.0 nm, including in the range from 1.0 to 1.5 nm, are generally suitable.

Once the barrier layer has been grown, a recessed gate can be formed in the barrier or in a gate trench layer disposed over the barrier. The recessed gate can be fabricated using a slow atomic level etching process that minimizes damage to etch a deep vertical trench into the barrier or trench layer and filling the trench with the gate metal. ALD may be used to deposit the gate metal in the trench to provide uniform deposition. Metal can then be deposited over the recessed portion of the gate using a metal deposition process to form a T-gate.

### Etch Stops.

Some embodiments of the HEMTs include an etch stop to facilitate the fabrication of a recessed gate trench. The use of an etch stop for the recessed gate trench may be advantageous because it is difficult to achieve atomic layer precision of the etch depth. The etch stop may be provided by an additional material layer over the high aluminum content AlGaN, InAlN, or InGaAlN barrier layer. Alternatively, the high aluminum content barrier layer may itself act as an etch stop.

HEMTs with Additional Etch Stop Layers.

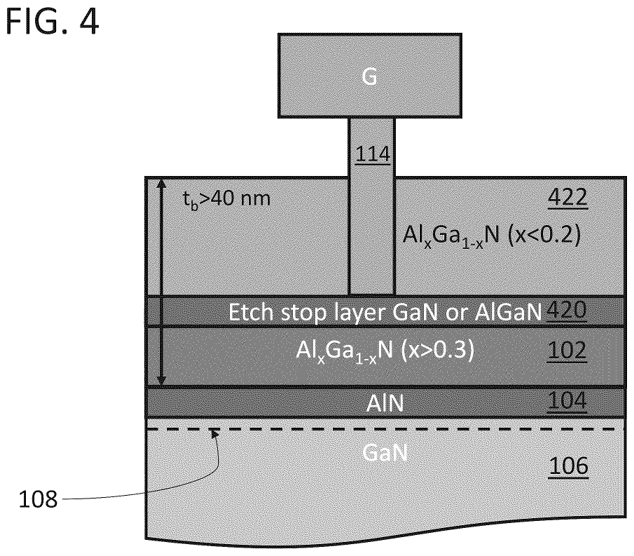

In some embodiments of the high-frequency AlGaN/GaN, InAlN/GaN, or InGaAlN/GaN-based HEMTs, an etch stop layer is deposited over the barrier layer and a trench layer, in which the trench for the recessed gate is formed, is deposited over the etch stop layer. An example of an active layer heterostructure for a HEMT that includes an etch stop 420, a trench layer 422, and a recessed gate 114 is illustrated in the schematic diagram of FIG. 4. In this example, trench layer 422 comprise an (Al,Ga)N alloy and has a relatively low Al content (typically lower than the Al content of barrier layer 102) in order to facilitate selective chemical etching, while etch stop layer 420 comprises an AlGaN alloy with an Al content higher than that of barrier layer 102, such that it acts as an etch stop for trench formation. (As used herein, the term “(Al,Ga)N alloy” refers to an AlGaN alloy having a uniform or graded AlGaN composition, or a superlattice comprising alternating layers of AlN and GaN.) In these HEMTs the Al content of an AlGaN etch stop layer should be at least 15 mol. % greater than the Al content in the underlying AlGaN, InAlN, or InGaAlN barrier layer to allow for selective chemical etching of the trench layer. In these embodiments, the thickness of the etch stop layer is typically, but not necessarily, no greater than 5 nm (e.g., 0.5 nm to 5 nm).

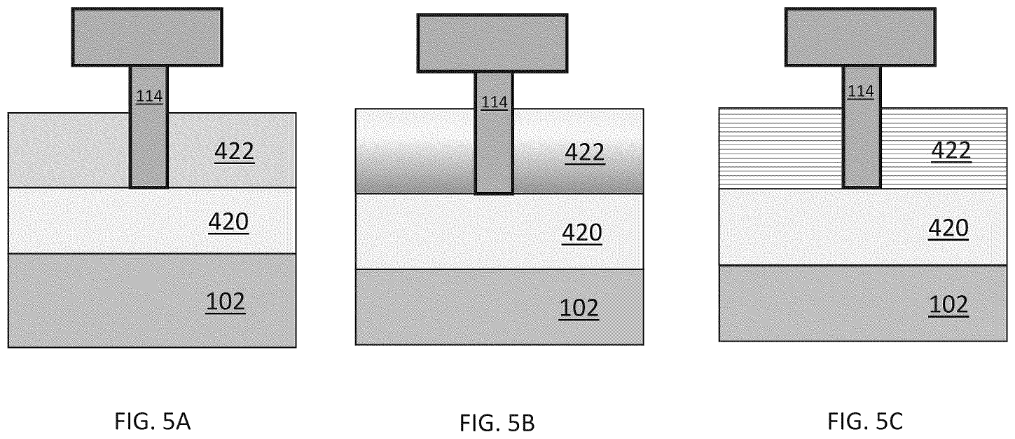

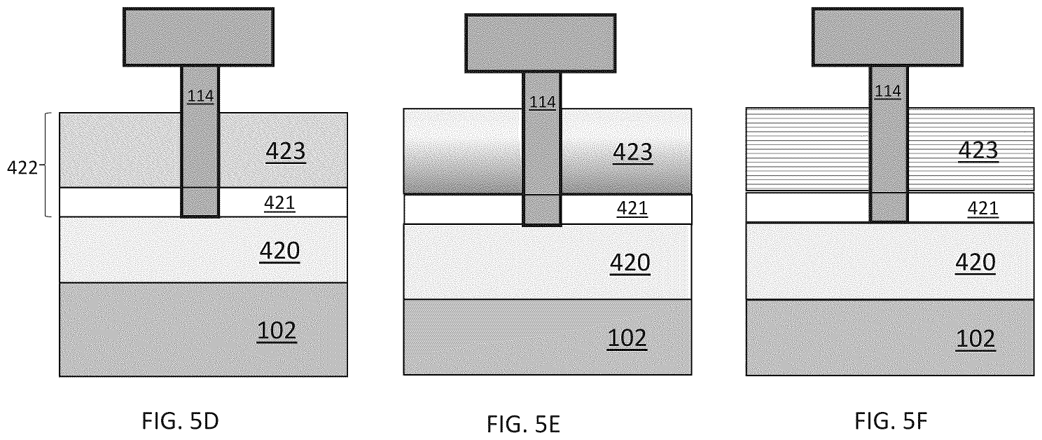

In these embodiments, the (Al,Ga)N alloy of trench layer 422 may be a single layer of AlGaN with a uniform composition (FIG. 5A), may by a graded AlGaN layer in which the Al content of the AlGaN alloy layer increases or decreases from the etch stop layer/trench layer interface to the upper surface of the trench layer (FIG. 5B), or may be an AlN/GaN superlattice structure (FIG. 5C) composed of alternating layers of AlN and GaN, in which the AlN layers are thinner than the GaN layers; alternatively, the alternating superlattice layers can be alternating layers of AlGaN and GaN, or alternating layers of AlGaN alloys with differing Al contents, where the Al content can vary between 10 mol. % to 100 mol. %. For embodiments of the trench layer 422 in which the layer is an AlN/GaN superlattice, the superlattice is considered to have a lower Al content than the etch stop layer by virtue of the presence of the AlN layers in the superlattice.

In some embodiments, trench layer 422 has two sublayers (FIGS. 5D-5F), wherein the lower trench sublayer 421 is composed of GaN or an AlGaN alloy having an Al content that is more than 20 mol. % lower than the Al content of the etch stop layer 422 and the upper trench sublayer 423 is as described above with reference to layer 422 in FIGS. 5A-5C. The use of a lower sublayer that is free from Al or that has a very low Al content can improve the selectivity of the chemical etch and the performance of etch stop layer 420.

While the high-frequency HEMTs that include an additional etch stop layer can benefit from the use of a thick barrier layer 102 (e.g., a barrier layer with a thickness of at least 30 nm), thinner barrier layers can be used. The thickness of the barrier material 102 and the combined thickness of the barrier layer 102, the etch stop layer 420, and the trench layer 422 can be selected to provide a HEMTs with a desired operating frequency, with lower barrier layer thicknesses generally corresponding to lower operating frequencies. In some of the HEMTs, the barrier layer will have a thickness in the range from about 5 nm to about 45 nm, or greater, and the combined thickness of the barrier layer, the etch stop layer, and the trench layer will be at least 10 nm, including combined thicknesses in the range from 10 nm to 20 nm, or greater. By way of illustration, a HEMT with a high-Al-content AlGaN barrier layer and an (Al,Ga)N trench layer that is designed to operate at 94 GHz may have a barrier layer thickness of about 10 nm and a combined barrier layer, etch stop layer, and trench layer thickness of at least 20 nm. By way of further illustration, a HEMT with a high-Al-content AlGaN barrier layer and an (Al,Ga)N trench layer that is designed to operate in a range from 140-220 GHz may have a barrier layer thickness of about 5 nm and a combined barrier layer, etch stop layer, and trench layer thickness of at least 10 nm.

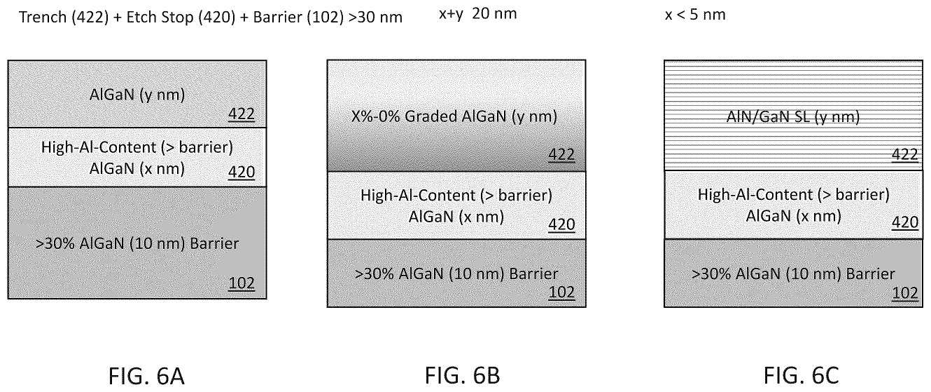

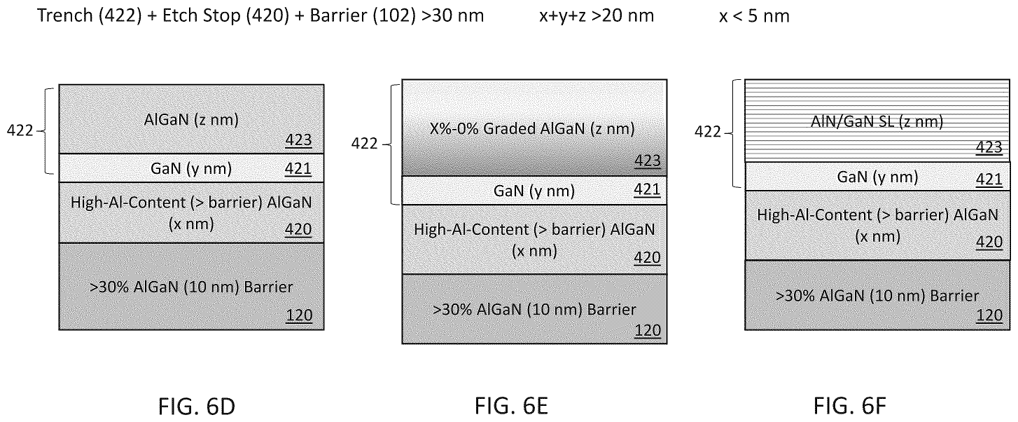

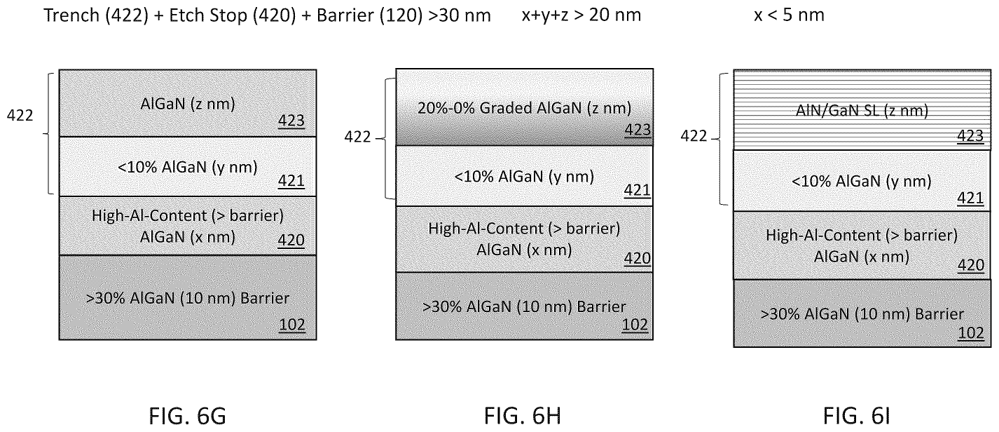

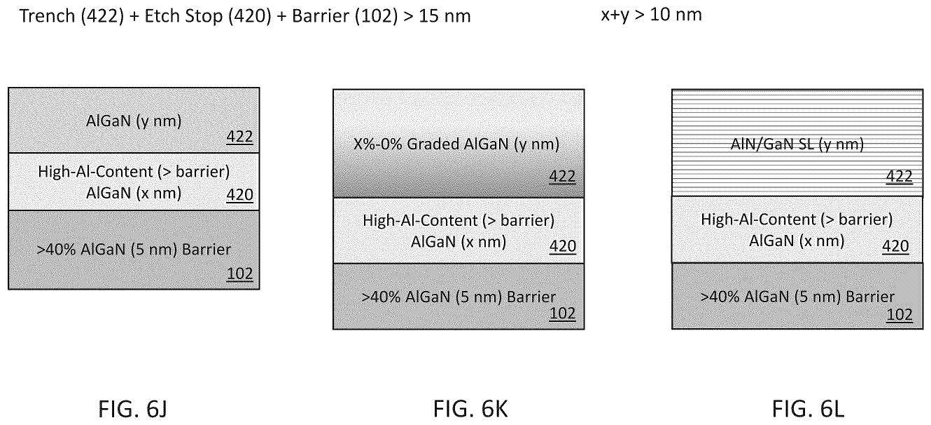

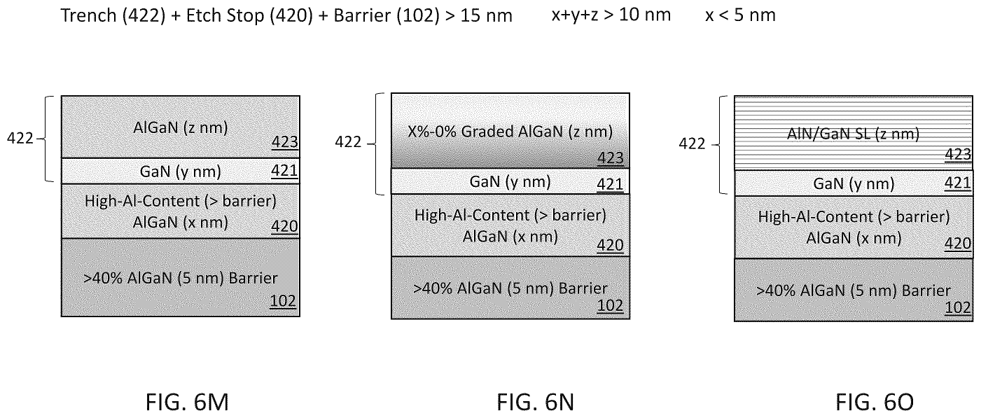

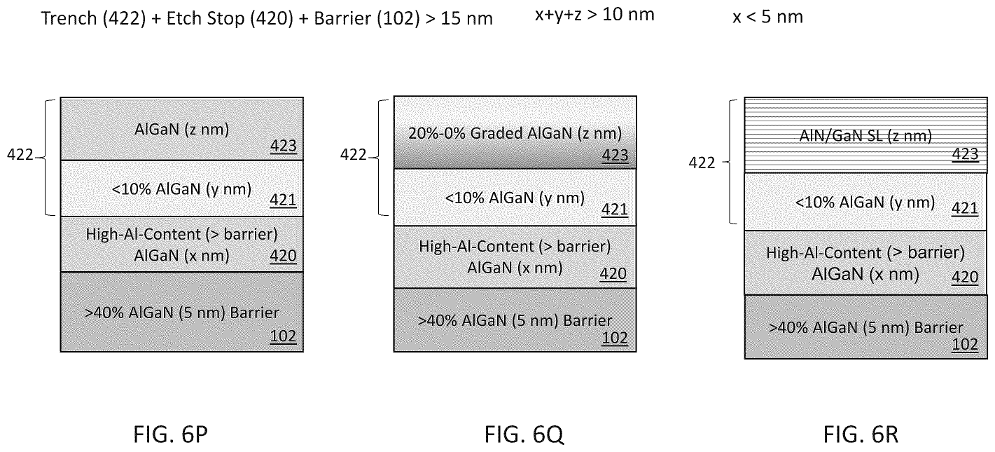

FIGS. 6A-6R depict non-limiting examples of barrier layer, etch stop layer, and trench layer combinations, with representative materials and layer thicknesses, that can be incorporated into the high-frequency HEMTs described herein. The heterostructures are shown prior to the etching of the trench. FIGS. 6A-6I depict HEMTs that operate at 94 GHz. FIGS. 6H-6R depict HEMTs that operate in the range from 140 to 220 GHz.

HEMTs that Use the High-Al-Content AlGaN, InAlN, or InGaAlN Barrier Layer as an Etch Stop.

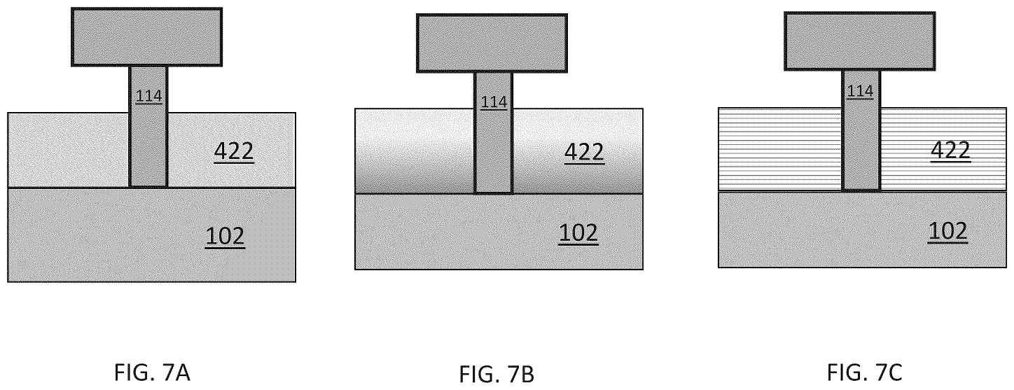

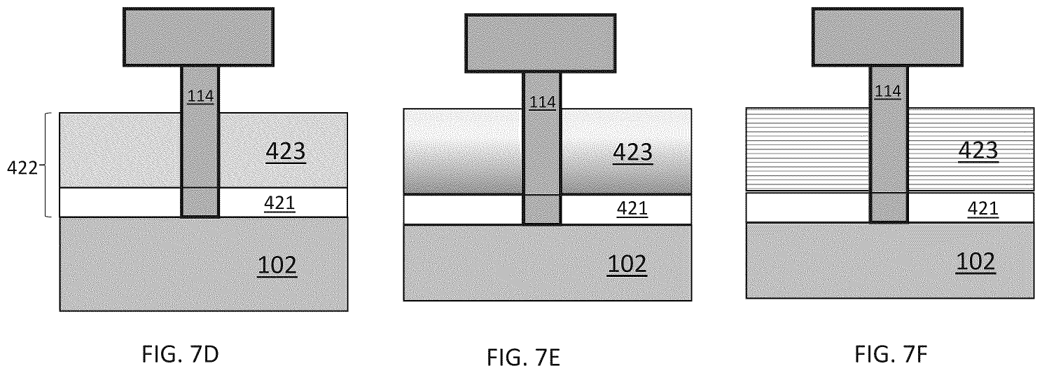

In some embodiments of the high-frequency AlGaN/GaN, InAlN/GaN, or InGaAlN/GaN-based HEMTs, the trench for the gate is recessed into a relatively low Al content (Al,Ga)N alloy trench layer disposed on the high-Al-content AlGaN, InAlN, or InGaAlN barrier layer, such that the high-Al-content group III-nitride material of the barrier acts as an etch stop layer, as well as a barrier layer. In these HEMTs the Al content in the trench layer is at least 15 mol. % lower than the Al content in the underlying AlGaN, InAlN, or InGaAlN barrier to allow for selective chemical etching of the trench layer. FIGS. 7A-7C are schematic diagrams illustrating a gate 114 recessed into a trench layer 422 comprising an (Al,Ga)N alloy, wherein a high-Al-content AlGaN barrier layer 102 acts as an etch stop. In these embodiments, the trench layer 422 may be a single layer of AlGaN alloy with a uniform composition (FIG. 7A), may by a graded AlGaN alloy layer in which the Al content of the layer increases or decreases from the barrier layer/trench layer interface to the upper surface of the trench layer (FIG. 7B), or may be an AlN/GaN superlattice structure (FIG. 7C) composed of alternating layers of AlN and GaN, in which the AlN layers are thinner than the GaN layers; alternatively, the alternating superlattice layers can be alternating layers of AlGaN and GaN, or alternating layers of AlGaN alloys with differing Al contents, where the Al content can vary between 10 mol. % to 100 mol. %.

In some embodiments, trench layer 422 has two sublayers (FIGS. 7D-7F), wherein the lower trench sublayer 421 is composed of GaN or an AlGaN alloy having an Al content that is more than 20 mol. % lower than the Al content of the AlGaN, InAlN, or InGaAlN barrier layer 102 and the upper trench sublayer 423 is as described above in reference to layer 422 in FIGS. 7A-7C. The use of a lower sublayer that is free from Al or that has a very low Al content can improve the selectivity of the chemical etch and the performance of the higher Al content AlGaN, InGaN, or InGaAlN barrier layer as an etch stop. In these embodiments, the thickness of the lower trench sublayer is typically, but not necessarily, no greater than 5 nm (e.g., 0.5 nm to 5 nm).

While the high-frequency HEMTs that utilize the high-Al-content AlGaN, InAlN, or InGaAlN barrier layer 102 as an etch stop can benefit from the use of a thick barrier layer (e.g., a barrier layer with a thickness of at least 30 nm), thinner barrier layers can be used. The thickness of the barrier material and the combined thickness of the barrier layer and the trench layer can be selected to provide a HEMTs with a desired operating frequency, with lower barrier thicknesses generally corresponding to lower operating frequencies. In some of the HEMTs, the barrier layer will have a thickness in the range from about 5 nm to about 45 nm, or greater, and the combined thickness of the barrier layer and the trench layer will be at least 10 nm, or at least 15 nm, including combined thicknesses in the range from 15 nm to 30 nm, or greater. By way of illustration, a HEMT with a high-Al-content AlGaN barrier layer and an (Al,Ga)N alloy trench layer that is designed to operate at 94 GHz may have a barrier layer thickness of about 10 nm and a combined barrier layer and trench layer thickness of at least 30 nm. By way of further illustration, a HEMT with a high-Al-content AlGaN barrier layer and an (Al,Ga)N alloy trench layer that is designed to operate in a range from 140-220 GHz may have a barrier layer thickness of about 5 nm and a combined barrier layer and trench layer thickness of at least 10 nm and, in some embodiments, at least 15 nm.

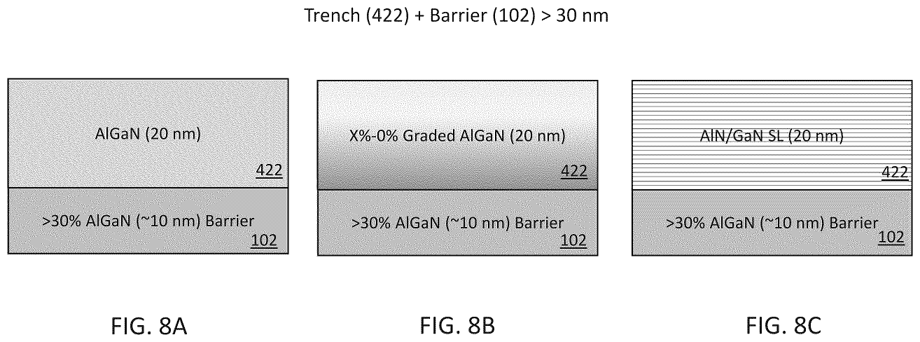

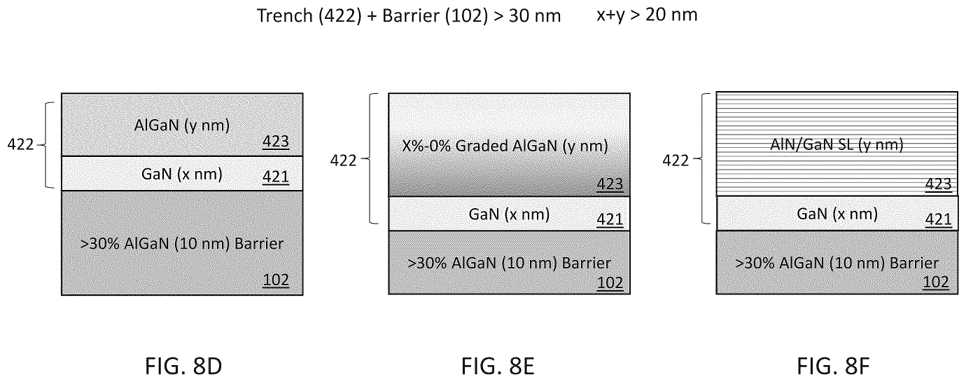

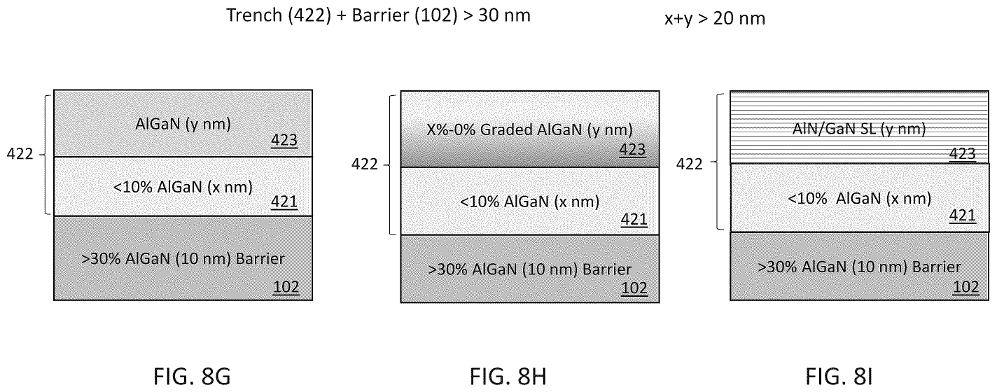

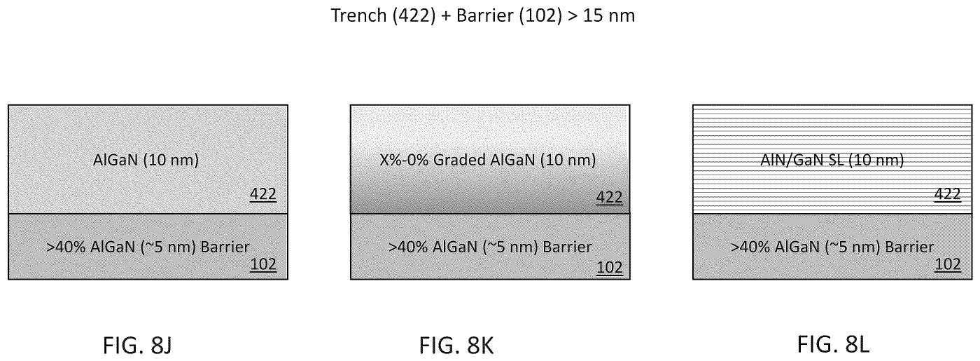

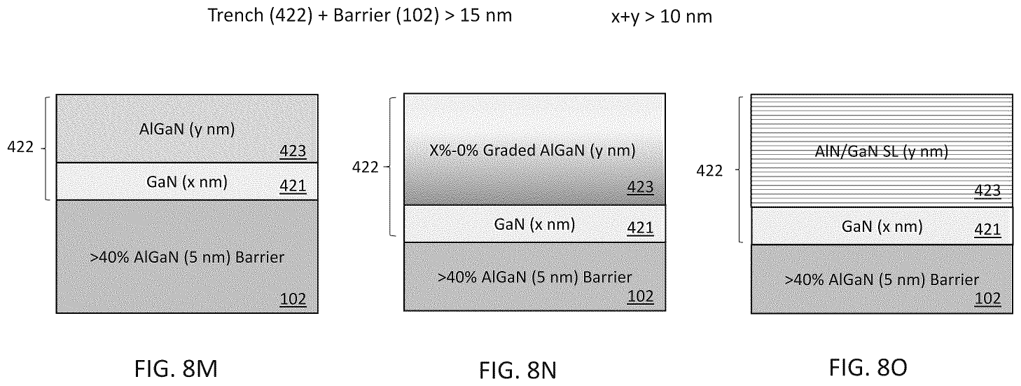

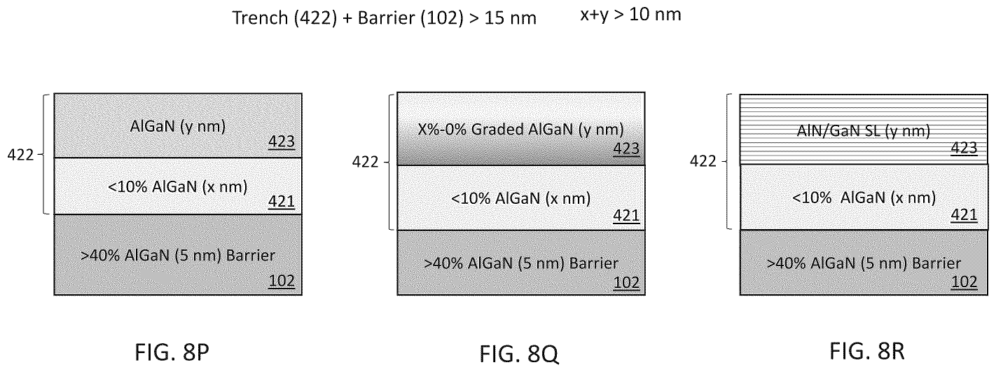

FIGS. 8A-8R depict non-limiting examples of barrier layer and trench layer combinations, with representative materials and layer thicknesses, that can be incorporated into the high-frequency HEMTs described herein. The heterostructures are shown prior to the etching of the trench. FIGS. 8A-8I depicts HEMTs that operate at 94 GHz. FIGS. 8H-8R depict HEMTs that operate in the range from 140 to 220 GHz.

### Other Embodiments

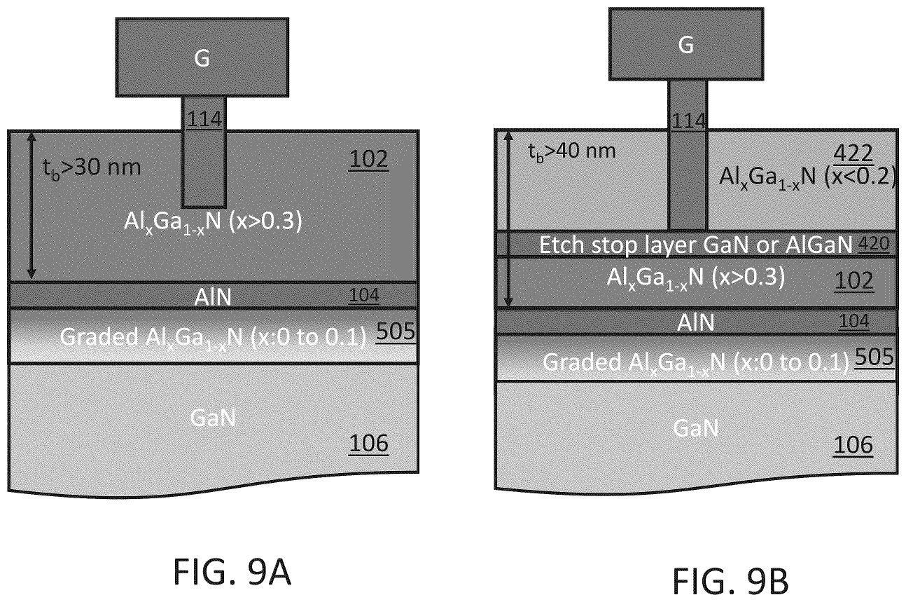

The high-frequency HEMTs of FIGS. 1-8R are used as illustrative examples. Numerous variations of the high-frequency HEMTs exist, as shown in FIGS. 9A and 9B, FIGS. 10A and 10B, and FIGS. 11A-11H. The HEMT heterostructures depicted in FIGS. 9A, 9B, 10A, 10B, and 11A-11H are AlGaN/GaN HEMTs. However, analogous heterostructure designs can be implemented in InAlN/GaN HEMTs and InGaAlN HEMTs. The layer thicknesses and Al concentrations other than those shown in FIGS. 9A, 9B, 10A, 10B, and 11A-11H can be used.

FIGS. 9A and 9B show AlGaN/GaN HEMTs in which the AlN layer 104 is grown on a graded AlₓGa₁₋ₓN buffer layer 505. In buffer layer 505, the Al mole fraction (x) increases through the layer thickness from the GaN channel/AlGaN buffer interface (106/505) to the AlGaN buffer/AlN interface (505/104) in order to offset the effects of the lattice mismatch between the GaN channel layer and AlN to facilitate the epitaxial growth of an AlN layer with high crystal quality. This HEMT design can be implemented without an etch stop layer (FIG. 9A) or with an etch stop layer 420 (FIG. 9B).

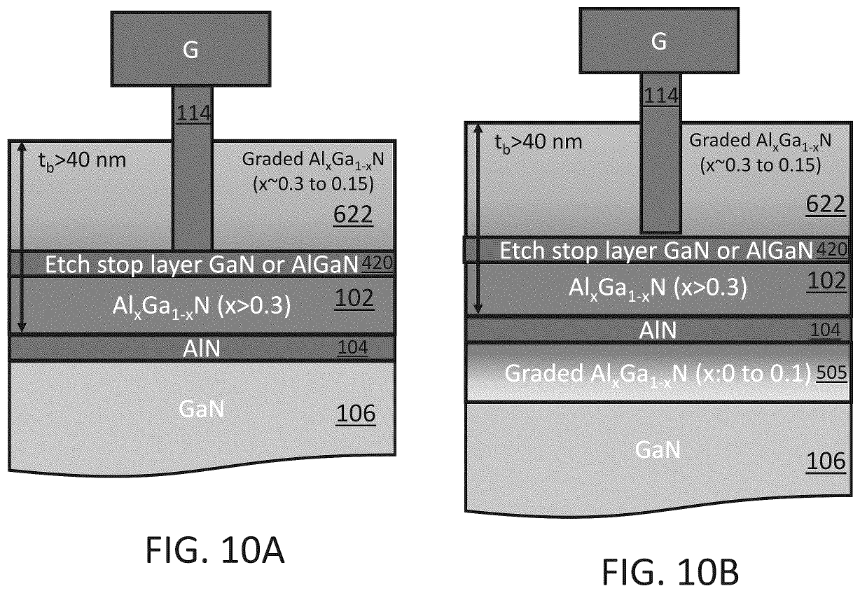

FIGS. 10A and 10B show AlGaN/GaN HEMTs that include etch stop 420 in which the barrier material 622 above etch stop 420 is graded such that the Al mole fraction (x) decreases through the layer thickness from the etch stop/upper barrier interface (420/522) to the exposed surface of the upper barrier 522 in order to offset the effects of the lattice mismatch between the etch stop layer and the AlGaN and facilitate the epitaxial growth of AlGaN layer 622 with a high crystal quality. This HEMT design can be implemented without a graded AlGaN buffer layer (FIG. 10A) or with a graded AlGaN buffer layer 505 (FIG. 10B).

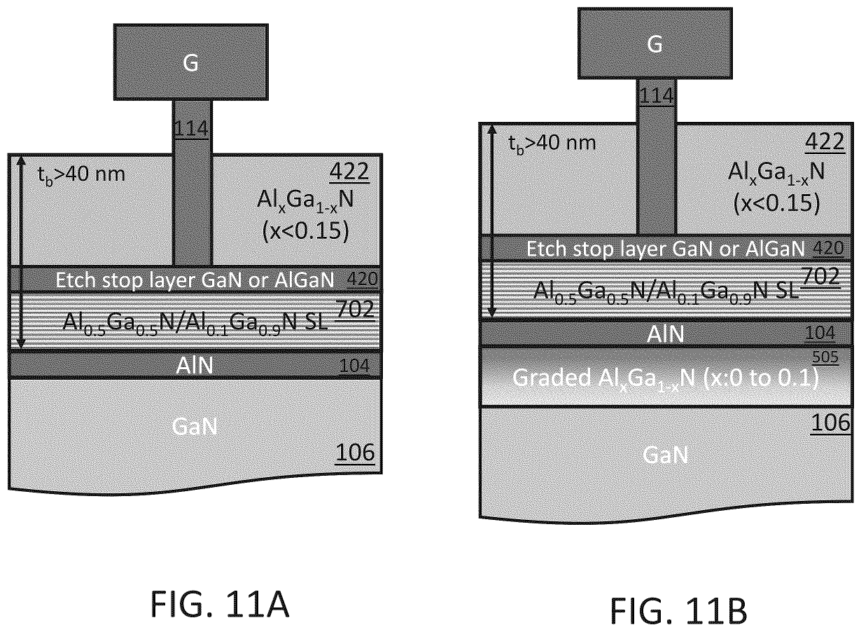

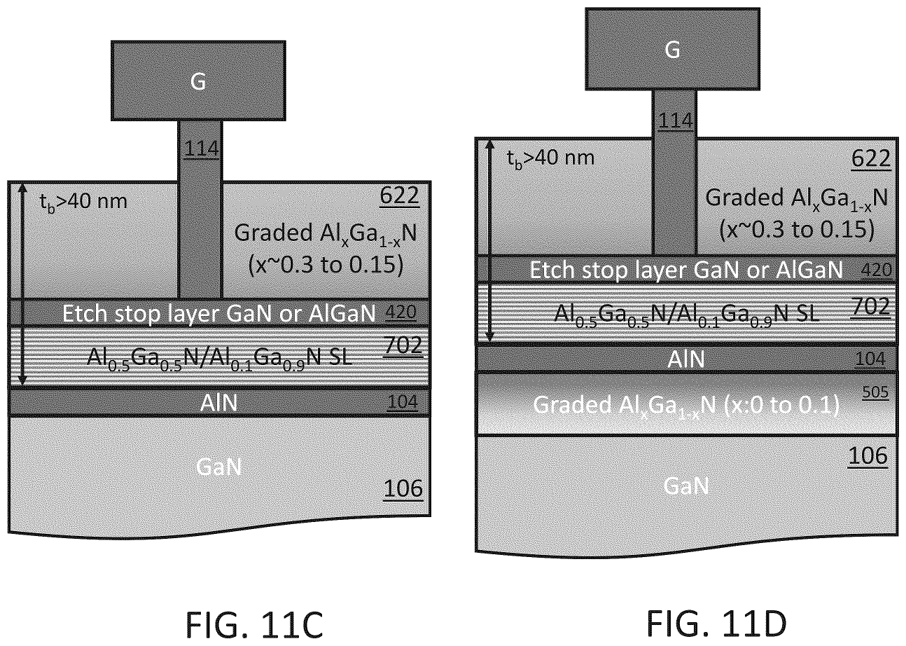

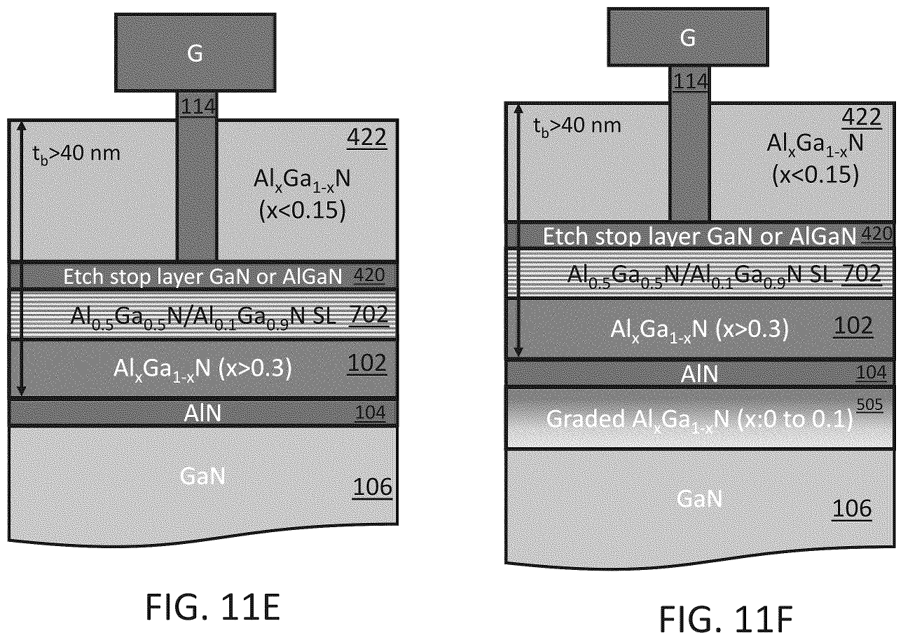

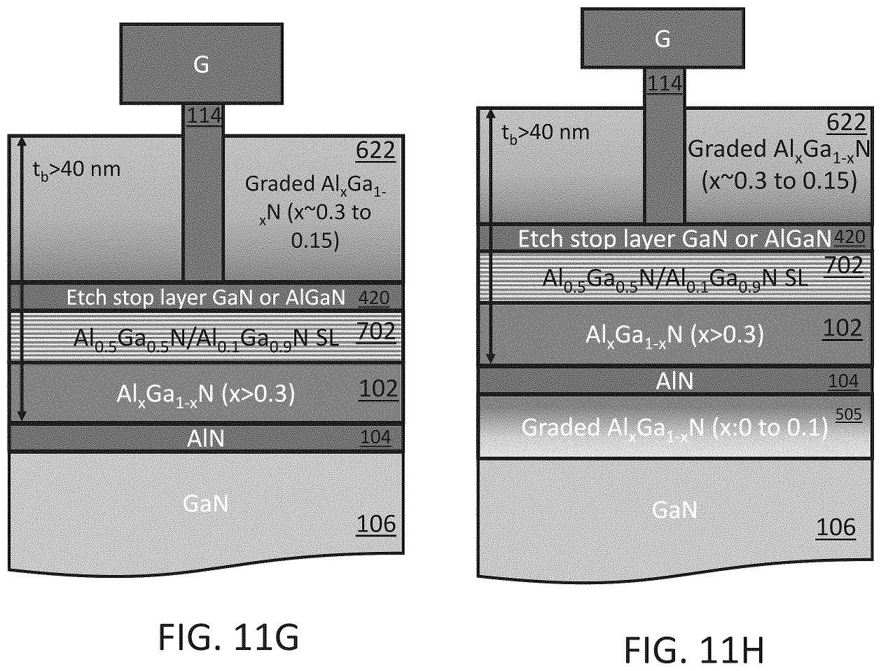

FIGS. 11A-11H show additional embodiments of the HEMTs that include an etch stop layer and a barrier comprising or consisting of a superlattice 702 (SL). Superlattice 702 comprises thin (e.g., 0.2 to 5 nm) alternating layers of a higher-Al concentration AlGaN and a lower-Al concentration AlGaN. Superlattice barriers can be used to improve the 2DEG electron mobility and carrier density in AlGaN/GaN HEMTs. The barrier of the HEMTs may consist of SL 702 (FIGS. 11A-11D). Alternatively, the barrier may include both an AlGaN barrier layer 102 and an overlying SL 702 (FIGS. 11E-11H). The SL barrier may be used in combination with a graded AlGaN buffer layer 505 (FIGS. 11B, 11D, 11F, and 11H), and/or a graded upper barrier 422 (FIGS. 11C, 11D, 11G, and 11H).

### AlN/AlGaN-Based High-Frequency HEMTs.

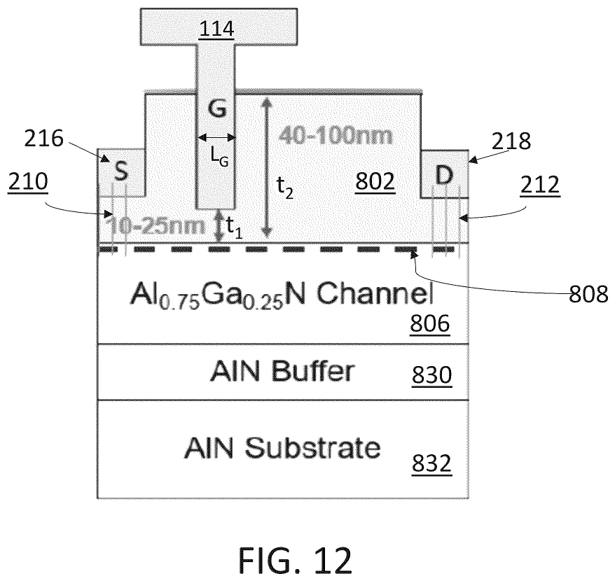

Another aspect of the invention provides HEMTs with an AlN/AlGaN structure having a thick AlN barrier layer and a recessed gate. One illustrative embodiment of such a HEMT is shown in the schematic diagram of FIG. 12. The HEMT includes an AlN barrier layer 802 and an AlₓGa₁₋ₓN channel layer 806, where 0.35<x<0.85. The layer thicknesses and Al concentration in the channel layer shown in the figure are for illustrative purposes only. Because the AlN has a wider bandgap than the AlₓGa₁₋ₓN, the bandgap discontinuity results in charge transfer from the AlN to the AlₓGa₁₋ₓN and accumulation of charge at the interface, resulting in the formation of a 2DEG 808 (dashed line) just below the interface. 2DEG 808 has a high electron density and a high electron mobility and acts as a channel for electron current to flow from a source (S) to a drain (D). A voltage applied to a gate 114 that is positioned above the 2DEG channel between the source and drain is used to modulate the flow of electrons in the 2DEG. As shown in FIG. 12, gate 114 may be a T-shaped gate to allow for a lower gate resistance. In the embodiment of the HEMT shown in FIG. 12, the source and drain comprise recessed annealed contacts 210, 212 that can be fabricated by removing part of the AlN and etching columns through the remaining AlN 802 and into AlGaN channel layer 806. A source contact 216 is disposed on recessed source 210 and a drain contact 218 is disposed on recessed drain 212. Alternatively, the source 110 and drain 112 may comprise regrown highly n-type (n⁺⁺) semiconductor materials. The highly n-type doped semiconductor material may have an n-type dopant concentration of, for example, at least 10²⁰/cm³.

During operation, a positive bias potential is applied to drain 212, while source 210 is grounded. As a result, an electron current flows from source 210 to drain 212, and this electron current is controlled by a potential applied to gate 114.

Barrier layer 802 has a thickness (t₂) of at least 10 nm (in some embodiments, at least 30 nm), which has the advantage of increasing the distance between the surface traps at the exposed barrier layer surface and the 2DEG in order to avoid current collapse during high-frequency operation. In some embodiments of the high-frequency HEMTs, barrier layer 802 has a thickness in the range from 40 nm to 100 nm. However, it is advantageous to have a thin barrier layer thickness between gate 114 and 2DEG 808 in order to improve the gate modulation and suppress short channel effects that can interfere with HEMT operation for high-frequency HEMTs, which have very small gate lengths. Thus, in the AlN/AlGaN HEMTs described herein, the gate is recessed into the barrier layer in order to reduce the thickness of the barrier locally between the recessed end of the gate and the 2DEG. This is shown in FIG. 12, where t₁ represents the thickness of the barrier layer beneath gate 114 and L_{G} is the gate length. Thickness t₁ is substantially lower than t₂, and t₂ is typically, but not necessarily, lower than 20t₁. The recessed gate high-frequency HEMTs may be designed for normally on (depletion mode) operation or for normally off (enhancement mode) operation. However, the primary purpose of the recessed-gate design is to achieve good modulation of the 2DEG, while simultaneously avoiding current collapse, rather than to provide enhancement mode operation.

Gate lengths for high-frequency AlN/AlGaN HEMTs operating at frequencies of of 1 GHz or higher are typically 250 nm or shorter. For example, high-frequency AlN/AlGaN HEMTs that operate in the frequency range from about 1 GHz to 100 GHz may have gate lengths in the range from 40 nm to 250 nm. This includes high-frequency HEMTs that operate at frequencies of 80 GHz or higher, 90 GHz or higher, and greater than 94 GHz having gate lengths in the range from 40 nm to 100 nm. (It should be understood, however, that the HEMTs described herein are not limited to those having gate lengths in these ranges or operating at these frequencies.) To achieve good gate modulation and high-frequency performance with such small gate lengths, the HEMTs can be fabricated with a ratio of L_{G} to t₁ (L_{G}/t₁) of at least 3 and more desirably an L_{G}/t₁ of at least 10.

Various metals and metal alloys can be used to form the source contact 210 and the contact 218 contacts, the recessed ohmic contacts 210, 212, and gate 114. By way of illustration only, the source, drain, and recessed ohmic contacts can be composed of titanium, aluminum, nickel, gold, or alloys thereof, and the gate may be composed of titanium, platinum, chromium, nickel, or alloys of titanium and tungsten. In one embodiment, the contacts comprise an alloy of nickel, silicon, and titanium that is formed by depositing respective layers of these materials, and then annealing them.

The various Group III-nitride layers, such as buffer layers, channel layers, barrier layers, and capping layers, of the high-frequency HEMTs can be grown using vapor deposition methods, such as metal-organic chemical vapor deposition (MOCVD), plasma chemical vapor deposition (CVD), or hot-filament CVD, or by molecular beam epitaxy. The metal contacts can be deposited by metal deposition techniques, such as atomic layer deposition (ALD), sputtering, or evaporation.

The HEMTs are grown epitaxially on a substrate 832 and may include buffer layers 830 and/or nucleation layers to facilitate the growth of high-quality crystalline layers epitaxially on a lattice mismatched substrate. For illustrative purposes, the substrate and buffer in FIG. 12 comprise AlN. The composition, grading, and thickness of any buffer layers will depend on the substrate upon which the active region of the HEMT is grown.

In addition, capping layers for offsetting current leakage and/or passivation layers for burying trapping states at the barrier layer surface to reduce current collapse may be deposited over the exposed surface of the AlN barrier layer.

The growth of the AlN/AlGaN HEMT heterostructure takes place in a vacuum chamber in which the substrate typically is supported on a rotatable platform. A heat source (e.g., a resistive heater) in thermal communication with the growing heterostructure can be used to tailor the growth temperature for each of the various layers to provide high-quality crystal growth. Typical growth temperatures include temperatures in the range from about 400° C. to about 1500° C. and, more commonly, in the range from about 1000° C. to about 1300° C.; however, suitable growth temperatures will depend on the particular material being grown.

Epitaxial growth using vapor deposition is carried out by exposing the substrate or the growing heterostructure to metal-containing and nitrogen-containing precursor molecules that decompose and react to form the various layers of the HEMT. These precursors may be introduced into the vacuum chamber with a carrier gas, such as hydrogen or nitrogen. For MOCVD growth, the precursors are metal organic compounds, such as trimethyl gallium (TMGa), triethyl gallium (TEGa), trimethyl aluminum (TMAl), or triethyl aluminum (TEAl). Ammonia (NH₃) is typically used as a nitrogen precursor molecule. For the growth of doped semiconductors, a dopant-containing precursor (e.g., silane for Si doping) is also introduced into the chamber.

The thickness of the AlGaN channel is typically in the range from about 50 nm to 2000 nm, including 1000 nm to 2000 nm. Thicknesses outside of this range can be used. However, a thicker channel layer has the advantage of increasing the distance between the 2DEG and carrier trapping states present at the interface between the AlGaN channel layer and the buffer layer on which the channel is grown. Like the trapping states at the surface of the barrier layer, these interface trapping states can contribute to current collapse.

Once the AlN barrier layer has been grown, a recessed gate can be formed in the barrier. This can be accomplished using a slow atomic level etching process that minimizes damage to etch a deep vertical trench into the barrier and filling the trench with the gate metal. ALD may be used to deposit the gate metal in the trench to provide uniform deposition. Metal can then be deposited over the recessed portion of the gate using a metal deposition process to form a T-gate.

### InAlN—AlGaN/AlN/GaN-Based High Frequency HEMTs.

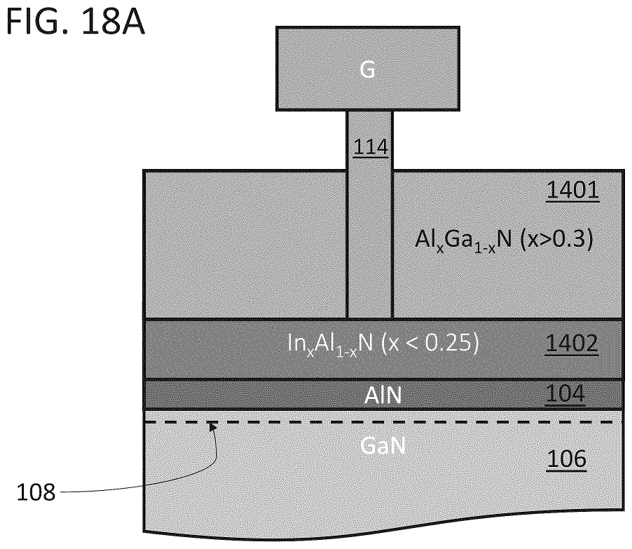

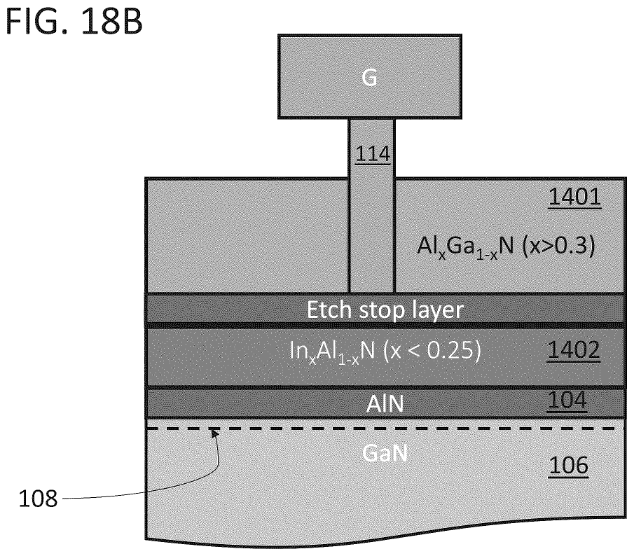

Another aspect of the invention (shown in FIGS. 18A and 18B) provides HEMTs with a bilayered barrier that includes a layer of AlₓGa₁₋ₓN 1401, where 0.3≤x (e.g., 0.3≤x<0.5) over a layer of InₓAl₁₋ₓN 1402, where x<0.25 (e.g., x<0.25). The HEMT further includes an unintentionally-doped, Ga-polar GaN channel layer 106, an AlN intervening layer 104, and a 2DEG 108 that acts as a channel for electron current to flow from a source (S) 110 to a drain (D) 112.

The properties, including thicknesses, of the unintentionally-doped, Ga-polar GaN channel layer 106 and AlN intervening layer 104 and the operating principles of the HEMT of FIG. 18A are as described above for the High-Frequency HEMTs with AlGaN, InAlN, or InGaAlN Barrier Layers. However, the individual and combined thicknesses of the AlGaN and InAlN layers need not be at least 30 nm. Optionally, an AlₓIn_{y}Ga_{1-(x+y)}N, where 0≤x≤1, 0≤x≤1, and (x+y)≥0 etch stop layer, may be grown between the layer of AlGaN 1401 and the layer of InAlN 1402, as shown in FIG. 18B.

Variations of the InAlN—AlGaN/AlN/GaN-Based High Frequency HEMTs may have annealed contacts, of the type shown in FIG. 2 and/or may include graded AlGaN barriers between the unintentionally-doped, Ga-polar GaN channel layer 106 and the an AlN intervening layer, as illustrated in FIGS. 9B, 10B, 11B, 11D, 11F, and 11H.

### Example

### Epitaxial Growth of AlGaN/AlN/GaN Heterostructure for Use as Active Layers in a High-Frequency HEMT.

This example illustrates the growth of a AlGaN/AlN/GaN HEMT structure on a c-plane sapphire substrate with an AlGaN barrier layer having an Al concentration of 36%, a GaN channel layer having a thickness of 31 nm, a sheet resistance as low as 249 Ω/□ at room temperature, and a very high mobility of 7830 cm²/V·s at cryogenic temperatures.

### Experiment:

The AlGaN/AlN/GaN heterostructure was grown using MOCVD on standard Fe-doped GaN on c-plane sapphire templates using tri-methyl gallium (TMGa), tri-ethyl gallium (TEGa), and tri-methyl aluminum (TMAl) as metal-organic precursors along with ammonia (NH₃) as the group-V precursor. H₂ was used as a carrier gas. A thick, unintentionally-doped (UID)-GaN layer (thickness t₁) was initially grown on top of solvent-cleaned Fe-doped semi-insulating GaN on sapphire templates using 90 μmol/min of TMGa and 283 mmol/min slm of NH₃. Next, a 40 nm GaN channel was grown using TEGa followed by a thin AlN layer (thickness t₂) together with a thick Al_{0.36}Ga_{0.64}N layer (thickness t₃) with a V/III ratio of 2600 at 1210° C. or 1153° C. throughout the growth of the layers. The TMAl flow was 5.18 μmol/min and the TEGa flow was 22 μmol/min.

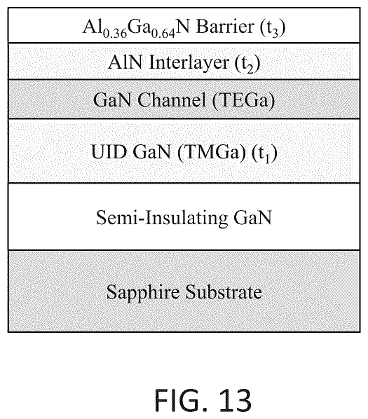

For obtaining a thick and high-Al concentration barrier layer for a AlGaN/AlN/GaN HEMT with low sheet resistance (<250 Ω/□), a series of experiments was performed to optimize the growth conditions and understand the effect of different growth parameters on the 2DEG electron mobility. Multiple parameters were varied—growth temperature (to demonstrate the effect of background carbon composition), the thickness t₁ of the intermediate UID-GaN channel layer (to demonstrate the effect of the distance between the channel and the interface between the semi-insulating GaN layer and the channel layer), the thickness t₂ of the AlN layer (to demonstrate the effect of alloy scattering), and finally the thickness t₃ of the AlGaN layer (to demonstrate its effect on the channel resistance). The final epitaxial structure design was grown using optimized growth conditions obtained by varying all of the above parameters. The epitaxial layer structure is shown in FIG. 13. The Al composition in each AlGaN barrier layer was kept constant throughout the epitaxial growth of that layer. Growth parameters are listed in Table 1.

TABLE 1
Growth parameters of different samples

| | UID-GaN | AlN thickness | Al_{0.36}Ga_{0.64}N | Growth |
|---|---|---|---|---|
| Sample | thickness (nm) | (nm) | thickness (nm) | Temperature |
| No. | (t₁) | (t₂) | (t₃) | (° C.) |
| 1 | 200 | 0.7 | 21 | 1210 |
| 2 | 200 | 0.7 | 21 | 1153 |
| 3 | 200 | 1.2 | 21 | 1210 |
| 4 | 1000 | 0.7 | 21 | 1210 |
| 5 | 1000 | 0.7 | 31 | 1210 |
| 6 | 1000 | 1.2 | 31 | 1210 |

After the growth of the heterostructures, the sheet resistance, mobility, and charge were measured using Hall measurements by the Van Der Pauw method. The surface morphology was analyzed using atomic force microscopy (AFM) measurements with Bruker Icon AFM in tapping mode. For analyzing the composition of the AlGaN barrier layer, Omega-2Theta scans were performed on calibration runs and defect densities were compared from omega rocking curve FWHM measurements, using high-resolution XRD Panalytical Empyrean.

### Results and Discussion:

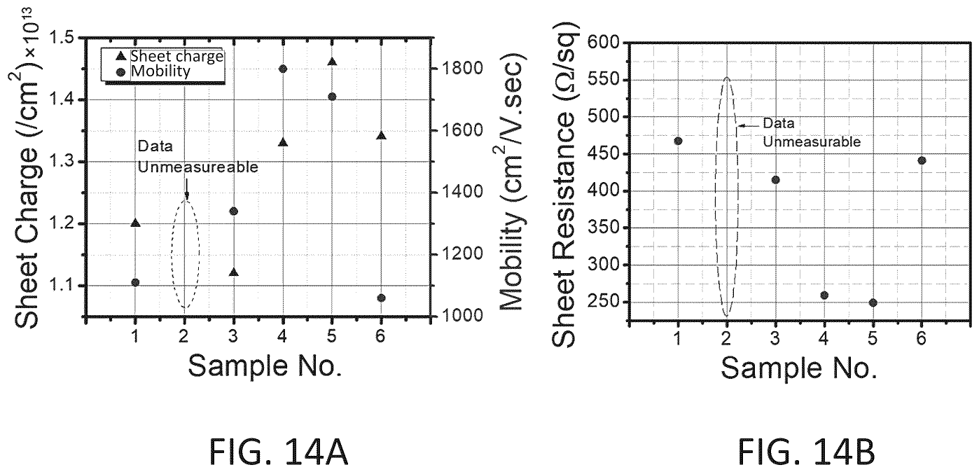

Hall measurements were performed on all the samples as feedback for growth condition optimizations. From FIG. 14A, the highly resistive behavior of sample 2 grown at a lower growth temperature of 1153° C. was observed, as Hall measurements did not detect any current flow, which can potentially be attributed to the increase in the carbon incorporation from the metal-organic sources used during the film deposition of the epitaxial structure. A lower growth temperature results in inefficient pyrolysis of the metal organic sources, trapping carbon in the grown films that act as scattering centers and may also trap electrons. Thus, the channel becomes extremely resistive and surface morphology becomes rough. The interface between AlN/GaN might also become rough at lower temperatures, causing increased interface roughness scattering, causing a sharp decrease in mobility. Moreover, the high-quality AlN interlayer is generally grown at high temperatures, thus low-temperature growth (1153° C.) might have degraded the quality. Therefore, a higher growth temperature of 1210° C. was used instead of 1153° C. for all other samples to reduce the carbon incorporation. It was ensured that the growth mode remained in the mass transport limited regime (T<1210° C.) rather than the desorption limited regime that can lead to desorption of GaN grown with H₂ carrier gas at elevated temperatures.

To understand the effect of alloy scattering, the AlN thickness (t₂) was increased from 0.7 nm to 1.2 nm in sample 3 compared to sample 1. The 2DEG mobility of sample 3 increased compared to sample 1 from 1110 cm²/V·s to 1340 cm²/V·s, while the sheet charge density decreased slightly from 1.2×10¹³/cm² to 1.12×10¹³/cm². The improved mobility signifies a reduction in alloy scattering with increasing AlN thickness. The reason behind the decrease in charge will be described later.

In sample 4, the thickness of the UID-GaN layer (t₂) was increased from 200 nm to 1 μm, which caused a significant change in the 2DEG mobility from 1110 cm²/V·s (sample 3) to 1800 cm²/V·s. In addition, the sheet charge density increased from 1.2×10¹³/cm² (sample 3) to 1.33×10¹³/cm². The possible reason behind the increase in mobility and sheet charge density is increasing the distance between the 2DEG channel and the interface between the UID-GaN (TMGa) and the semi-insulating GaN template. The semi-insulating layer is doped with Fe, which helps to trap the background carriers in the GaN layer. If the 2DEG channel is in close proximity to the Fe-doped semi-insulating layer, then the electron transport might get affected due to bulk trapping phenomenon.

Increasing the AlGaN layer thickness (t₃) from 21 nm to 31 nm in sample 5 compared to sample 4 increased the sheet charge density from 1.33×10¹³/cm² (sample 4) to 1.46×10¹³/cm² due to a reduction in surface depletion, while the 2DEG mobility reduced from 1800 cm²/V·s to 1710 cm²/V·s compared to sample 4. A probable reason is the strain-induced mobility reduction in the channel.

Finally, in sample 6, the alloy scattering was reduced by increasing the thickness of AlN (t₂) from 0.7 nm to 1.2 nm while keeping the AlGaN thickness (t₃) 31 nm. This degraded the 2DEG mobility from 1710 cm²/V·s to 1060 cm²/V·s and also reduced the sheet charge density from 1.46×10¹³/cm² to 1.34×10¹³/cm². FIG. 14B shows the overall sheet resistances of different samples. At low temperatures (77 K), sample 4 and sample 5 showed Hall mobilities of 8570 cm²/V·s and 7830 cm²/V·s, which are comparable (>5500 cm²/V·s) with the state-of-the-art (<300 Ω/□) low-temperature mobilities recorded for thick and high-Al concentration AlGaN barrier HEMT structures. This proves that the AlN/GaN interface is extremely smooth, and material quality in the channel is significantly high. (Gaska, et al., 1998; Ding, et al., 2010; Wang, et al., Journal of Crystal Growth 289, no. 2 (Apr. 1, 2006): 415-18.)

TABLE 2
Comparative data between sample 4 and sample 5

| | Hall Measurement | | | | | | |
|---|---|---|---|---|---|---|---|
| | | μ | μ | | | Omega rocking | |
| | nₛ | (cm²/ | (cm²/ | | | curve | |
| Sample | (cm⁻²) × | V · s) | V · s) | R_{SH} | R^{a} | FWHM | FWHM |
| No. | 10¹³ | (300K) | (77K) | (Ω/□) | (nm) | (002) | (102) |
| 4 | 1.33 | 1800 | 8570 | 259 | 0.42 | 138.7 | 658.57 |
| 5 | 1.46 | 1710 | 7830 | 249 | 0.27 | 136.29 | 452.37 |

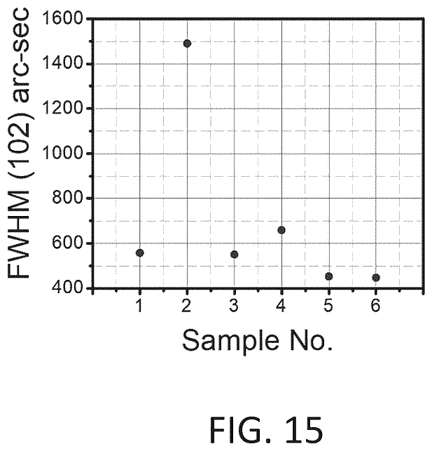

To understand the reason behind the highly resistive behavior of sample 2 compared with others in more detail, X-ray diffraction (XRD) rocking curve measurements were done. The XRD omega-rocking curve measurement provides crucial information about the degradation of the electron mobility of sample 2 with a growth temperature of 1153° C. FIG. 15 shows that the full width at half maximum (FWHM) (102) measured by the omega-rocking curve of sample 2 is extremely high (1490 arc-sec), indicating very high edge dislocation density. This also indicates the possibility of excessive carbon incorporation and rough interface as well as poor quality of the AlGaN barrier and AlN interlayer. Other samples showed similar kinds of off-axis (102) FWHM values, showing the variation of the defect density was minimum. On-axis (002) FWHM values of all the samples were near about 130-150 arc-sec (not shown in the figure), addressing very low screw dislocation density.

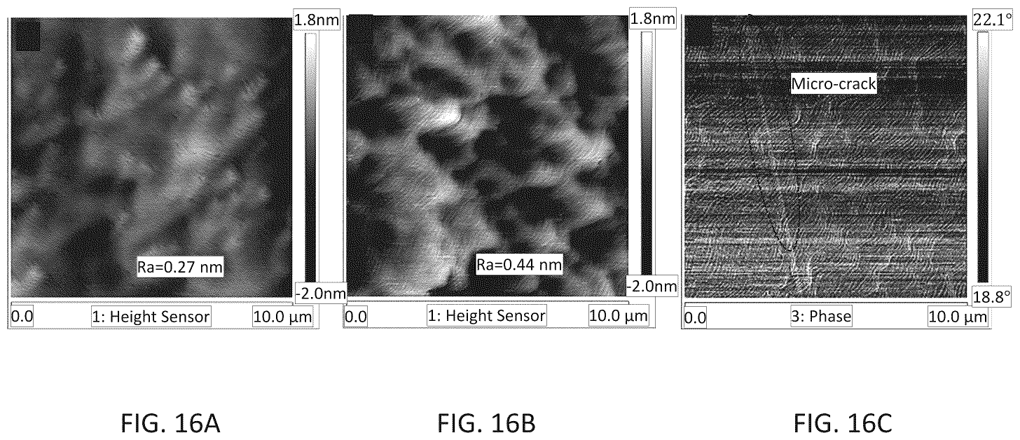

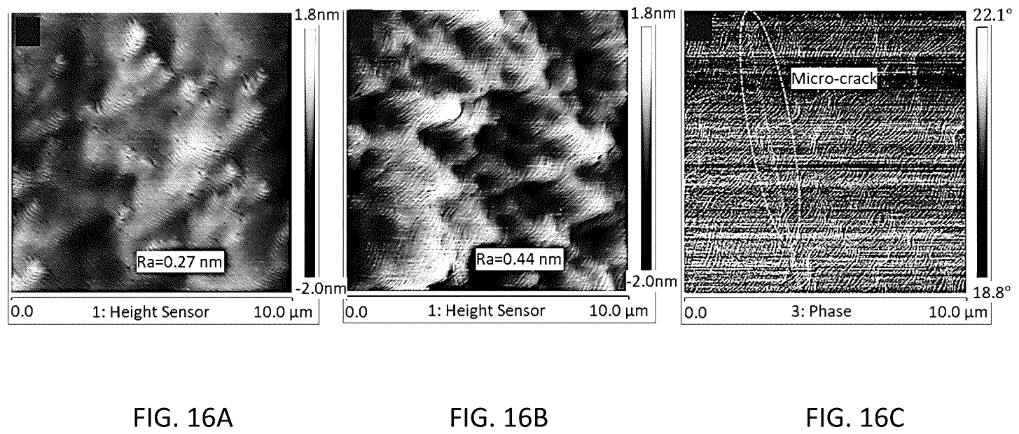

Though the XRD fails to provide much information about the degradation in sheet charge density from 1.46×10¹³/cm² to 1.34×10¹³/cm² in between sample 5 (t₂=0.7 nm) and sample 6 (t₂=1.1 nm) respectively, these can be understood while analyzing the surface roughness of these samples using AFM. In FIG. 16A and FIG. 16B, the AFM scans (10 μm×10 μm) of sample 5 and sample 6 are displayed. The surface roughness increased in sample 6 by 0.17 nm compared to sample 5 and more step bunching appeared. Also, FIG. 16C shows that there are micro-cracks present in sample 6. Therefore, with a higher AlN thickness (1.2 nm) along with a thicker AlGaN (t₁=31 nm) layer, the strain in the barrier layer became extremely high and was enough to generate micro-cracks in sample 6. With a thicker AlN layer, sample 6 showed a lower sheet charge density in the channel due to increased interface roughness and possibly degraded interface quality. For sample 6 (1.2 nm thick AlN layer) the AFM roughness increased by a factor of 63% compared to sample 5 with a thinner (0.7 nm) AlN layer. The large degradation of the 2DEG mobility in sample 6 can be understood from FIG. 16C. Micro-cracks will increase the scattering in the 2DEG significantly, thus decreasing the carrier mobility.

From the above analyses, it can be seen that to get a thick (>10 nm or >30 nm), high-Al concentration (>35%), crack-free AlGaN barrier layer HEMT with very low sheet resistance (<250 Ω/□), the growth process needs to be precisely tailored. The experimental data proves that it is possible to grow high-quality and high-mobility AlGaN/AlN/GaN HEMT structures on sapphire with very low sheet resistance.

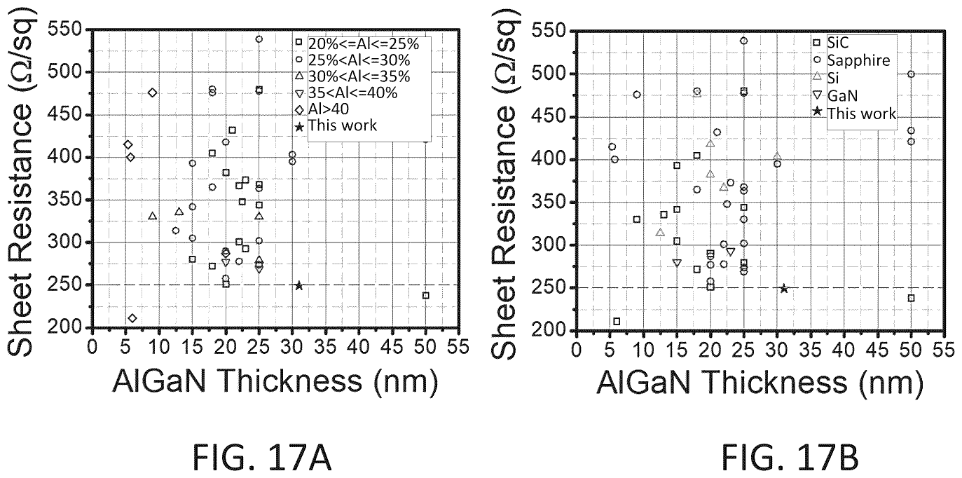

FIG. 17A shows the importance of this work. Most of the AlGaN/GaN HEMTs that have been reported previously having ˜250 Ω/□ or lower sheet resistance either have a thinner barrier layer (≤25 nm) or lower Al concentration (≤30%) in the AlGaN barrier. It is clear from FIG. 17A that obtaining low sheet resistance with thicker (>30 nm) and high-Al concentration (>35%) AlGaN barrier is not trivial. The combination of a high barrier thickness, high Al concentration in the AlGaN, and low sheet resistance will ensure high power RF operation with reduced gate leakage, increased breakdown voltage and high cut-off frequency. FIG. 17B shows that the high-performance HEMTs are mostly grown on SiC substrates. However, this example demonstrates a state-of-the-art and simple AlGaN/AlN/GaN HEMT design on sapphire that can operate at a similar level as a GaN HEMT grown on SiC or GaN substrates, which are extremely costly. (The previously reported data is from: Yamada, et al., 2021; Wang, et al., 2007; Gaska, et al., 1998; Gustafsson, Sebastian et al. IEEE Transactions on Electron Devices 62, no. 7 (July 2015): 2162-69; Kumar, V. et al. IEEE Electron Device Letters 23, no. 8 (August 2002): 455-57; Wong, Yuen-Yee et al., 2012 10th IEEE International Conference on Semiconductor Electronics (ICSE), 729-32, 2012; Bergsten, Johan et al., IEEE Transactions on Electron Devices 63, no. 1 (January 2016): 333-38; Hao, Yue et al., IEEE Electron Device Letters 32, no. 5 (May 2011): 626-28; Shen, L. et al., IEEE Electron Device Letters 22, no. 10 (October 2001): 457-59; Palacios, T. et al., IEEE Electron Device Letters 27, no. 6 (June 2006): 428-30; Kumazaki, Yusuke et al., IEEE Transactions on Electron Devices 69, no. 6 (June 2022): 3073-78; Palacios, T. et al., IEEE Electron Device Letters 27, no. 1 (January 2006): 13-15; Hu, Weiguo et al., Superlattices and Microstructures 46, no. 6 (Dec. 1, 2009): 812-16; Gong, Jia-Min et al., Chinese Physics Letters 33, no. 11 (November 2016): 117303; Aggerstam, T. et al., Thin Solid Films, Proceedings of the Eighth International Conference on Atomically Controlled Surfaces, Interfaces and Nanostructures and the Thirteenth International Congress on Thin Films, 515, no. 2 (Oct. 25, 2006): 705-7; Miyoshi, Makoto et al., Solid-State Electronics 50, no. 9 (Sep. 1, 2006): 1515-21; Ding, GuoJian et al., Science China Physics, Mechanics and Astronomy 53, no. 1 (Jan. 1, 2010): 49-53; Zhang, Haochen et al., Applied Physics Letters 119, no. 7 (Aug. 16, 2021): 072104; Wang, X. L. et al., Solid-State Electronics 49, no. 8 (Aug. 1, 2005): 1387-90; Mahaboob, Isra et al., IEEE Journal of the Electron Devices Society 7 (2019): 581-88; Wang, Xiaoliang et al., Physica Status Solidi c 3, no. 3 (2006): 607-10; Miyoshi, Makoto et al., Japanese Journal of Applied Physics 44, no. 9R (Sep. 8, 2005): 6490; Cai, Yong et al., IEEE Electron Device Letters 26, no. 7 (July 2005): 435-37; Palacios, T. et al., IEEE Electron Device Letters 26, no. 11 (November 2005): 781-83; Wang, Cuimei et al., Journal of Crystal Growth 289, no. 2 (Apr. 1, 2006): 415-18; Li, Haoran et al., Japanese Journal of Applied Physics 53, no. 9 (Aug. 29, 2014): 095504; Wang, Cuimei et al., Applied Surface Science 253, no. 2 (Nov. 15, 2006): 762-65; Zhang, Kai et al., Physica Status Solidi (a) 212, no. 5 (2015): 1081-85; Cheng, Jianpeng et al., Applied Physics Letters 106, no. 14 (Apr. 6, 2015): 142106; Ubukata, Akinori et al., Journal of Crystal Growth, 16th International Conference on Metalorganic Vapor Phase Epitaxy, 370 (May 1, 2013): 269-72; Zhang, Jialin et al., IEEE Electron Device Letters 39, no. 11 (November 2018): 1720-23; Bouzid-Driad, S. et al., IEEE Electron Device Letters 34, no. 1 (January 2013): 36-38; Latrach, S. et al., Current Applied Physics 17, no. 12 (Dec. 1, 2017): 1601-8; Xu, Xiaoqing et al., AIP Advances 6, no. 11 (November 2016): 115016; “Room Temperature 2DEG Mobility Above 2350 Cm2/V·s in AlGaN/GaN HEMT Grown on GaN Substrate SpringerLink.” Accessed Dec. 4, 2022; Yu, Hao et al., IEEE Transactions on Electron Devices 68, no. 11 (November 2021): 5559-64.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” can mean only one or can mean “one or more.” Embodiments of the inventions consistent with either construction are covered.

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

If not already included, all numeric values of parameters in the present disclosure are proceeded by the term “about” which means approximately. This encompasses those variations inherent to the measurement of the relevant parameter as understood by those of ordinary skill in the art. This also encompasses the exact value of the disclosed numeric value and values that round to the disclosed numeric value.

What is claimed is:

1. A high electron mobility transistor comprising:
a channel layer comprising Ga-polar unintentionally-doped GaN;
a barrier layer comprising AlₓGa₁₋ₓN where 0.3≤x, InₓAl₁₋ₓN, where x<0.25, or InₓGa_{y}Al_{1-(x+y)}N, where (x+y)<0.8;
an AlN intervening layer disposed between the channel layer and the barrier layer;
a two-dimensional electron gas confined in the channel layer;
an etch stop layer on the barrier layer, the etch stop layer comprising AlN or an AlGaN alloy having an aluminum content at least 15 mol. % greater than the aluminum content of the barrier layer;
a trench layer on the etch stop layer, the trench layer comprising an (Al,Ga)N alloy having an aluminum content at least 15 mol. % lower than the aluminum content of the etch stop layer;
a source in electrical communication with the two-dimensional electron gas;
a drain in electrical communication with the two-dimensional electron gas; and
a gate between the source and the drain, wherein a portion of the gate is recessed through the trench layer down to the etch stop layer.

2. The high electron mobility transistor of claim 1, wherein the barrier layer, etch stop layer, and trench layer have combined thickness of at least 10 nm.

3. The high electron mobility transistor of claim 1, where in the barrier layer comprises the AlₓGa₁₋ₓN, where 0.30≤x<0.5.

4. The high electron mobility transistor of claim 1, wherein the aluminum content of the (Al,Ga)N alloy of the trench layer is graded through the thickness of the trench layer.

5. The high electron mobility transistor of claim 1, wherein the (Al,Ga)N alloy of the trench layer has an AlN/GaN superlattice structure or an AlGaN/GaN superlattice structure.

6. The high electron mobility transistor of claim 1, wherein the trench layer comprises a first sublayer comprising either GaN or an AlGaN alloy having an Al content of less than 10 mol. % on the etch stop layer and a second sublayer comprising the (Al,Ga)N alloy having an aluminum content at least 15 mol. % lower than the aluminum content of the etch stop layer.

7. The high electron mobility transistor of claim 1, wherein the AlₓGa₁₋ₓN, InₓAl₁₋ₓN, or InₓGa_{y}Al_{1-(x+y)}N of the barrier layer has a graded composition.

8. The high electron mobility transistor of claim 1, wherein the AlₓGa₁₋ₓN, InₓAl₁₋ₓN, or InₓGa_{y}Al_{1-(x+y)}N of the barrier layer has a superlattice structure.

9. The high electron mobility transistor of claim 1, further comprising a layer comprising graded AlₓGa₁₋ₓN, where x ranges from 0 to 0.1 disposed between the AlN interlayer and the channel layer.

10. A high electron mobility transistor comprising:
a channel layer comprising Ga-polar unintentionally-doped GaN;
a barrier layer comprising AlₓGa₁₋ₓN where 0.3≤x, InₓAl₁₋ₓN, where x<0.25, or InₓGa_{y}Al_{1-(x+y)}N, where (x+y)<0.8;
an AlN intervening layer disposed between the channel layer and the barrier layer;
a two-dimensional electron gas confined in the channel layer;
a trench layer on the barrier layer, the trench layer comprising an (Al,Ga)N alloy having an aluminum content at least 15 mol. % lower than the aluminum content of the AlₓGa₁₋ₓN, InₓAl₁₋ₓN, or InₓGa_{y}Al_{1-(x+y)}N in the barrier layer;
a source in electrical communication with the two-dimensional electron gas;
a drain in electrical communication with the two-dimensional electron gas; and
a gate between the source and the drain, wherein a portion of the gate is recessed through the trench layer down to the barrier layer.

11. The high electron mobility transistor of claim 10, wherein the barrier layer and trench layer have combined thickness of at least 10 nm.

12. The high electron mobility transistor of claim 10, where in the barrier layer comprises the AlₓGa₁₋ₓN, where 0.30≤x<0.5.

13. The high electron mobility transistor of claim 10, wherein the aluminum content of the (Al,Ga)N alloy of the trench layer is graded through the thickness of the trench layer.

14. The high electron mobility transistor of claim 10, wherein the (Al,Ga)N alloy of the trench layer has an AlN/GaN superlattice structure.

15. The high electron mobility transistor of claim 10, wherein the trench layer comprises a first sublayer either GaN or an AlGaN alloy having an Al content of less than 10 mol. % on the barrier layer and a second sublayer comprising the (Al,Ga)N alloy having an aluminum content at least 10 mol. % lower than the aluminum content of the barrier layer.

16. The high electron mobility transistor of claim 10, wherein the AlₓGa₁₋ₓN, InₓAl₁₋ₓN, or InₓGa_{y}Al_{1-(x+y)}N of the barrier layer has a graded composition.

17. The high electron mobility transistor of claim 10, wherein the AlₓGa₁₋ₓN, InₓAl₁₋ₓN, or InₓGa_{y}Al_{1-(x+y)}N of the barrier layer has a superlattice structure.

18. The high electron mobility transistor of claim 10, further comprising a layer comprising graded AlₓGa₁₋ₓN, where x ranges from 0 to 0.1 disposed between the AlN interlayer and the channel layer.

19. A high electron mobility transistor comprising:
a channel layer comprising Ga-polar unintentionally-doped GaN;
a barrier layer having a thickness, t₂, of at least 10 nm and comprising AlₓGa₁₋ₓN where 0.3≤x, InₓAl₁₋ₓN, where x<0.25, or InₓGa_{y}Al_{1-(x+y)}N, where (x+y)<0.8;
an AlN interlayer disposed between the channel layer and the barrier layer;
a two-dimensional electron gas confined in the channel layer;
a source in electrical communication with the two-dimensional electron gas;
a drain in electrical communication with the two-dimensional electron gas; and
a gate between the source and the drain, wherein a portion of the gate is recessed into the AlₓGa₁₋ₓN, InₓAl₁₋ₓN, or InₓGa_{y}Al_{1-(x+y)}N.

20. The high electron mobility transistor of claim 19, wherein the barrier layer comprises the AlₓGa₁₋ₓN.
